(19) United States
(12) Patent Application Publication
(10) Pub. No.: US 2021/0071076 A1
(43) Pub. Date: Mar. 11, 2021

(54) LUMINESCENT NANOPARTICLES AND LUMINESCENT SOLAR CONCENTRATORS CONTAINING SAME

(71) Applicant: National University of Singapore, Singapore (SG)

(72) Inventors: Zhi Kuang TAN, Singapore (SG); Hadhi WlJAYA, Singapore (SG); Daryl DARWAN, Singapore (SG)

(21) Appl. No.: 16/982,397

(22) PCT Filed: Apr. 4, 2019
(86) PCT No.: PCT/SG2019/050194

§ 371 Date: Sep. 18, 2020

Related U.S. Application Data
(60) Provisional application No. 62/652,481, filed on Apr. 4, 2018.

(51) Int. Cl. C09K 11/08; C09K 11/74; C09K 11/70; C09K 11/88; C09K 11/02; H01L 31/048; H01L 31/0352; H01L 31/0304

(52) U.S. Cl. CPC C09K 11/0883; C09K 11/7492; C09K 11/703; C09K 11/883; B82Y 20/00; H01L 31/0488; H01L 31/035218; H01L 31/0304; C09K 11/02

(57) ABSTRACT

Disclosed herein are luminescent nanoparticles comprising In₁₋ₓZnₓAs and In_{1-y}Zn_{y}P, wherein x is from 0 to 0.5, y is from 0 to 0.6, and the molar ratio of In₁₋ₓZnₓAs to In_{1-y}Zn_{y}P is from 1:4 to 1:5000. In a preferred embodiment, the luminescent nanoparticles are InAs—In(Zn)P—ZnSe—Zn S quaternary giant-shell quantum dots that possess efficient photoluminescence in the near-infrared region with a large Stokes shift and minimal reabsorption. The core-shell nanoparticles may be particularly useful in the formation of a luminescent solar concentrator when used as part of a composite material formed from the nanoparticles and a suitable polymer. Also disclosed herein are methods to manufacture the nanoparticles, the composite materials and solar concentrators.

### CROSS-REFERENCE TO RELATED APPLICATIONS

The present application is a filing under 35 U.S.C. 371 as the National Stage of International Application No. PCT/SG2019/050194, filed Apr. 4, 2019, entitled “LUMINESCENT NANOPARTICLES AND LUMINESCENT SOLAR CONCENTRATORS CONTAINING SAME,” which claims priority to U.S. Provisional Patent Application No. 62/652,481 filed with the United States Patent and Trademark Office on Apr. 4, 2018 and entitled “LUMINESCENT SOLAR CONCENTRATORS,” both of which are incorporated herein by reference in their entirety for all purposes.

### FIELD OF INVENTION

The invention relates to core-shell nanoparticles that may be applied in the formation of large-area, neutral-coloured luminescent solar concentrators, amongst other applications.

### BACKGROUND

The listing or discussion of a prior-published document in this specification should not necessarily be taken as an acknowledgement that the document is part of the state of the art or is common general knowledge.

Photovoltaic technology is close to its development limit. Crystalline silicon solar cell technology and thin-film cadmium telluride technology have reported power conversion efficiencies of 26.1% and 22.1%, respectively (see NREL. NREL Efficiency Chart, <www.nrel.gov/pv/assets/images/efficiency-chart.png> (2018)), which are close to their theoretical limits defined by Shockley and Queisser (Shockley, W. & Queisser, H. J. Journal of Applied Physics 32, 510-519 (1961)), and possess operational lifetimes in excess of 20 years. The new frontier in solar energy research therefore lies in the development non-intrusive transparent solar modules that could be seamlessly integrated into buildings and facades for energy generation. Luminescent solar concentrators (LSC) hold significant promise in this respect, and were first proposed in 1977 by Goetzberger and Greube in 1977 (Goetzberger, A. & Greube, W. Applied physics 14, 123-139 (1977)). LSCs rely on luminescent compounds embedded in a transparent matrix to absorb, re-emit and direct light to the edges of the panel through total internal reflection. The wave-guided light is therefore “concentrated” at the edges of the panel and could be collected by conventional solar cells for electrical generation. This is an elegant concept, but efforts so far have failed to push this technology towards commercialization, primarily due to efficiency losses caused by reabsorption. The reabsorption losses occur when light travels towards the panel edges, and are caused by the overlap between the absorption and emission spectra of the luminescent materials. This problem worsens with the increase in panel dimensions, hence making LSC technology impractical for large-area building integration. Recent developments in luminescent giant-shell quantum dots have helped to mitigate the reabsorption problem, and works by creating a large Stoke's shift between the absorption and emission profile (Meinardi, F., et al., Nature Photonics 8, 392 (2014)). However, the use of highly-toxic cadmium compounds in these quantum dots is a significant deterrent towards their implementation in commercial consumer products.

### SUMMARY OF INVENTION

Aspects and embodiments of the invention are described with respect to the following numbered clauses.
1. Luminescent nanoparticles comprising:
   In₁₋ₓZnₓAs; and
   In_{1-y}Zn_{y}P, wherein
   x is from 0 to 0.5, such as from 0.02 to 0.33;
   y is from 0 to 0.6, such as from 0.02 to 0.5; and
   the molar ratio In₁₋ₓZnₓAs to In_{1-y}Zn_{y}P is from 1:4 to 1:5000, such as from 1:10 to 1:1000, such as from 1:25 to 1:200 (e.g. 1:50).
2. The nanoparticles according to Clause 1, wherein x is 0 and/or y is 0.
3. The nanoparticles according to Clause 1 or Clause 2, wherein the nanoparticle has an average diameter of from 2 to 100 nm, such as from 5 to 20, nm, such as from 8 to 15 nm.
4. The nanoparticles according to any one of the preceding clauses, wherein the nanoparticles further comprise one or more of ZnSeS, ZnSe, and ZnS.
5. The nanoparticles according to Clause 4, wherein the molar ratio of Zn to Se, S or the combined total of Se and S is from 0.1 to 1 to 10:1, such as 0.5 to 1 to 2:1, such as 1:1.
6. The nanoparticles according to Clause 4 or Clause 5, wherein the molar ratio of In to Zn is from 0.1 to 1 to 10:1, such as 0.5 to 1 to 2:1, such as 1:1, optionally wherein:
(a) when one of ZnSeS, ZnSe, and ZnS is present, the molar ratio of In to Zn is from 0.1 to 1 to 10:1, such as 0.5 to 1 to 3:1, such as 2:1;
(b) when two of ZnSeS, ZnSe, and ZnS is present, the molar ratio of In to Zn is from 0.1 to 1 to 10:1, such as 0.5 to 1 to 2:1, such as 1:1; or
(c) when all three of ZnSeS, ZnSe, and ZnS is present, the molar ratio of In to Zn is from 0.1 to 1 to 10:1, such as 0.5 to 1 to 2:1, such as 1:2.
7. The nanoparticles according to any one of the preceding clauses, wherein the nanoparticles comprise:
   (a) InAs and InP;
   (b) InAs, InP and ZnSe;
   (c) InAs, InP and ZnS;
   (d) InAs, InP, ZnSe and ZnS; and
   (e) In_{1-y}Zn_{y}P and ZnSeS, where x is from 0.02 to 0.33 and y is from 0.02 to 0.5.
8. The nanoparticles according to any one of the preceding clauses, wherein the nanoparticles have a photoluminescence peak and an absorption edge, where the photoluminescence peak is red-shifted from 50 to 250 nm, such as 75 to 150 nm away, such as 100 nm away from the absorption edge.
9. The nanoparticles according to Clause 8, wherein the photoluminescence peak is from 700 to 1100 nm, such as from 800 to 1000 nm.
10. The core-shell nanoparticle according to Clause 8 or Clause 9, wherein the absorption edge is from 600 to 1000 nm, such as from 700 to 900 nm.
11. The nanoparticles according to any one of the preceding clauses, wherein:
   the molar ratio of to As is from 5:1 to 1:1, such as 2:1; and/or
   the molar ratio of In_{1-y}Zn_{y} to As is from 5:1 to 1:1, such as 2:1.
12. The nanoparticles according to any one of the preceding clauses, wherein the nanoparticles are core-shell nanoparticles.
13. The nanoparticles according to Clause 12, where the nanoparticles comprise:
   a core of In₁₋ₓZnₓAs and a shell layer of In_{1-y}Zn_{y}P surrounding the In₁₋ₓZnₓAs core; or
   a core of In_{1-y}Zn_{y}P and a shell layer of In₁₋ₓZnₓAs surrounding the In_{1-y}Zn_{y}P core, wherein:
   the molar ratio of In₁₋ₓZnₓAs to In_{1-y}Zn_{y}P is from 1:4 to 1:5000, such as from 1:10 to 1:1000, such as from 1:25 to 1:200 (e.g. 1:50);
   x is from 0 to 0.5, such as from 0.02 to 0.33; and
   y is from 0 to 0.6, such as from 0.02 to 0.5.
14. The nanoparticles according to Clause 13, wherein:
   the In₁₋ₓZnₓAs core has a diameter of from 10 to 50 Å, such as 15 to 25 Å, such as 20 Å; or
   the In_{1-y}Zn_{y}P core has a diameter of from 30 to 110 Å, such as 50 to 90 Å, such as 70 Å.
15. The nanoparticles according to Clause 13 or Clause 14, wherein:
   the nanoparticle has a diameter of from 2 to 100 nm, such as from 5 to 20, nm, such as from 8 to 15 nm; and/or
   x is 0; and/or
   y is 0.
16. The nanoparticles according to any one of Clauses 12 to 15, wherein the nanoparticle further comprises one or more shells selected from ZnSeS, ZnSe, and ZnS, optionally wherein the molar ratio of Zn to Se, S or the combined total of Se and S is from 0.1 to 1 to 10:1, such as 0.5 to 1 to 2:1, such as 1:1.
17. The nanoparticles according to any one of Clauses 12 to 16, wherein the nanoparticles have a structure of:
   (a) InAs/InP;
   (b) InAs/InP/ZnSe;
   (c) InAs/InP/ZnS;
   (d) InAs/InP/ZnSe/ZnS; and
   (e) In₁₋ₓZnₓAs/In_{1-y}Zn_{y}P/ZnSeS, where x is from 0.02 to 0.33 and y is from 0.02 to 0.5.
18. The nanoparticles according to any one of Clauses 12 to 17, wherein the nanoparticles have a photoluminescence peak and an absorption edge, where the photoluminescence peak is red-shifted from 50 to 250 nm, such as 75 to 150 nm away, such as 100 nm away from the absorption edge.
19. The nanoparticles according to Clause 18, wherein the photoluminescence peak is from 700 to 1100 nm, such as from 800 to 1000 nm.
20. The nanoparticles according to Clause 18 or Clause 19, wherein the absorption edge is from 600 to 1000 nm, such as from 700 to 900 nm.
21. The nanoparticles according to any one of Clauses 12 to 20, wherein:
   in the In₁₋ₓZnₓAs core or shell layer, the molar ratio of to As is from 5:1 to 1:1, such as 2:1; and/or
   in the In_{1-y}Zn_{y}P core or shell layer, the molar ratio of In_{1-y}Zn_{y} to As is from 5:1 to 1:1, such as 2:1.
22. A composite material comprising:
   a luminescent nanoparticle material according to any one of Clauses 1 to 21; and
   a polymeric material, wherein the luminescent nanoparticle material is homogeneously dispersed throughout a matrix formed by the polymeric material.
23. The composite material according to Clause 22, wherein the polymeric material is a vinyl polymer or copolymer, optionally wherein the polymer is polymethylmethacrylate or polystyrene and the copolymer is formed from methyl methacrylate or styrene and an oligomer having vinyl terminal groups.
24. The composite material according to Clause 22 or Clause 23, wherein:
(a) when the luminescent nanoparticle is a core-shell luminescent nanoparticle as described in any one of Clauses 12 to 21, then the polymeric material further comprises InP core-shell nanoparticles selected from the group consisting of InP/ZnSeS or, more particularly, InP/ZnSe/ZnS, InP/ZnSe and InP/ZnS, optionally wherein the diameter of the InP core-shell nanoparticles is from 2 nm to 100 nm; and/or
(b) when the luminescent nanoparticle is as described in any one of Clauses 1 to 11, then the polymeric material further comprises nanoparticles selected from the group consisting of: InP and ZnSeS; or, more particularly, InP, ZnSe and ZnS; InP and ZnSe; and InP and ZnS, optionally wherein the diameter of these nanoparticles are from 2 nm to 100 nm.
25. The composite material according to Clause 24(a), wherein the weight ratio of the nanoparticles having an In₁₋ₓZnₓAs or In_{1-y}Zn_{y}P core to the nanoparticles selected from the group consisting of InP/ZnSeS or, more particularly, InP/ZnSe/ZnS, InP/ZnSe and InP/ZnS is from 1:10 to 1:100, such as from 1:15 to 1:30, such as 1:20.
26. A luminescent solar concentrator comprising a layered material having at least one edge, wherein the layered material comprises at least one layer of a composite material according to any one of Clauses 22 to 25 sandwiched between at least two transparent substrate layers.
27. The solar concentrator according to Clause 26, wherein the at least two transparent substrate layers are selected from one or more of glass, a polymeric material and combinations thereof.
28. The solar concentrator according to Clause 26 or Clause 27, wherein the average transmittance of the concentrator is from 5 to 95%, such as from 20 to 80%.
29. The solar concentrator according to any one of Clauses 26 to 28, wherein the composite material is patterned into shapes, words or images.
30. The solar concentrator according to any one of Clauses 26 to 29, wherein the concentrator further comprises one or more solar cells arranged along at least one edge of the layered material.
31. The solar concentrator according to Clause 30, wherein the at least one edge of the layered material is substantially covered by solar cells.
32. The solar concentrator according to Clause 30 or Clause 31, wherein at least one busbar is attached to the one or more solar cells and the busbar is attached to the solar cells in a manner that does not block the at least one edge of the layered material.
33. Use of a nanoparticle material according to any one of Clauses 1 to 21 or a composite material according to any one of Clauses 22 to 26 as a solar concentrator.
34. A method of forming a core-shell luminescent nanoparticle, which method comprises: providing a core of In₁₋ₓZnₓAs and forming a first shell of In_{1-y}Zn_{y}P on the core; or
   providing a core of In_{1-y}Zn_{y}P and forming a first shell of In₁₋ₓZnₓAs on the In_{1-y}Zn_{y}P core, wherein:
   wherein the molar ratio of In₁₋ₓZnₓAs to In_{1-y}Zn_{y}P is from 1:4 to 1:5000, such as from 1:10 to 1:1000, such as from 1:25 to 1:200 (e.g. 1:50);
   x is from 0 to 0.5, such as from 0.02 to 0.33; and y is from 0 to 0.6, such as from 0.02 to 0.5.
35. The method of Clause 34, wherein:
   the In₁₋ₓZnₓAs core has a diameter of from 10 to 50 Å, such as 15 to 25 Å, such as 20 Å; or
   the In_{1-y}Zn_{y}P core has a diameter of from 30 to 110 Å, such as 50 to 90 Å, such as 70 Å.
36. The method of Clause 33 or Clause 34, further comprising:
   (a) forming a second shell around the first shell, where the second shell is formed from ZnSeS, ZnSe or ZnS;
   (b) forming a second shell around the first shell, where the second shell is formed from ZnSe and forming a third shell around the second shell, where the third shell is formed from ZnS;
   (c) forming a second shell around the first shell, where the second shell is formed from ZnS and forming a third shell around the second shell, where the third shell is formed from ZnSe.
37. The method according to any one of Clauses 33 to 36, wherein the nanoparticle formed from the method has a diameter of from 2 to 100 nm, such as from 5 to 20, nm, such as from 8 to 15 nm.
38. The method according to any one of Clauses 33 to 37, wherein the nanoparticle has a photoluminescence peak and an absorption edge, where the photoluminescence peak is red-shifted from 50 to 250 nm, such as 75 to 150 nm away, such as 100 nm away from the absorption edge.
39. The method according Clause 38, wherein the photoluminescence peak is from 700 to 1100 nm, such as from 800 to 1000 nm.
40. The method according to Clause 38 or Clause 39, wherein the absorption edge is from 600 to 1000 nm, such as from 700 to 900 nm.

### DRAWINGS

FIG. 1. Forster resonance energy transfer in a close-packed quantum dot cluster.

FIG. 2. Design of busbars and fingers on silicon solar cell strips.

FIG. 3. Transmission electron microscope image of InAs/InP/ZnSe/ZnS quantum dots.

FIG. 4. Absorbance (A) and photoluminescence (B) spectra of InAs/InP/ZnSe/ZnS quantum dots.

FIG. 5. Absorbance (A) and photoluminescence (B) spectra of In(Zn)As/In(Zn)P/ZnSeS quantum dots.

FIG. 6. General coating method of resin onto glass.

FIG. 7. Photograph of a quantum dots-polymer composite film fabricated in an embodiment of the invention.

FIG. 8. Combined absorbance and photoluminescence spectra of InAs—In(Zn)P—ZnSe—ZnS quantum dots. Inset shows an image of the quantum dot solution.

FIGS. 9A and 9B. FIG. 9A Evolution of quantum dot absorbance during synthesis. Dashed lines trace the absorption edges of the InAs core and the In(Zn)P shell. FIG. 9B Evolution of quantum dot PL during synthesis. The dashed line traces the PL peak of the InAs core.

FIGS. 10A and 10B. FIG. 10A Transmission electron microscopy (TEM; scale bar denotes 50 nm) and FIG. 10B high-resolution TEM (scale bar denotes 5 nm) of InAs—In(Zn)P—ZnSe—ZnS quantum dots.

FIG. 11. Background-subtracted X-ray diffraction patterns of InAs, InAs—In(Zn)P, InAs—In(Zn)P—ZnSe, and InAs—In(Zn)P—ZnSe—ZnS core-shell quantum dots at various stages of the one-pot continuous-injection synthesis. Solid vertical lines show the X-ray scattering positions and intensities of bulk zinc blende structures of InAs, InP, ZnSe, and ZnS. Vertical dotted and dashed lines are shown for the three most intense reflections corresponding to the (111), (220), and (311) planes from the bulk materials of InAs and InP, respectively.

FIG. 12. Absorbance and photoluminescence spectra of InAs—In(Zn)P—ZnSe—ZnS quantum dots synthesised with 2× continuous injection speed (0.2 mL/min).

FIG. 13. Absorbance and photoluminescence spectra of InAs—In(Zn)P with a thin In(Zn)P shell (bottom panel) and the final giant shell InAs—In(Zn)P—ZnSe—ZnS quantum dots (top panel).

### DESCRIPTION

The current invention relates to the formation of non-toxic quantum dots that overcome some or all of the problems identified hereinbefore. Thus, there is disclosed Luminescent nanoparticles comprising:
In₁₋ₓZnₓAs; and
In_{1-y}Zn_{y}P, wherein
x is from 0 to 0.5, such as from 0.02 to 0.33;
y is from 0 to 0.6, such as from 0.02 to 0.5; and
the molar ratio In₁₋ₓZnₓAs to In_{1-y}Zn_{y}P is from 1:4 to 1:5000, such as from 1:10 to 1:1000, such as from 1:25 to 1:200 (e.g. 1:50).

Indium arsenide is a small bandgap III-V semiconductor that emits at approximately 850 nm. An 850 nm emission wavelength is optimal for absorption by silicon solar cells. In₁₋ₓZnₓAs, where x is greater than 0 and less than or equal to 0.5, such as from 0.02 to 0.33 may have similar properties and may be used accordingly.

It will be appreciated that the emission may occur at any value from 700 to 1100 nm in the nanoparticles disclosed herein. That is, the photoluminescence peak may be at any value from 700 to 1100 nm, such as from 800 to 1000 nm, though a photoluminescence peak of about 850 nm is preferred. When used herein, the term “about” may refer to a variance of ±5% of the value/range cited. In embodiments of the invention, the emission value/photoluminescence peak of from 700 to 1100 nm above may be derived from In₁₋ₓZnₓAs (e.g. InAs).

When used herein, the term “nanoparticle” should be interpreted to mean a material having a diameter of up to 300 nm. Examples of nanoparticles that may be mentioned herein include those where the nanoparticles have a diameter of from 2 to 100 nm, such as from 5 to 20, nm, such as from 8 to 15 nm. For the avoidance of doubt, when the diameter of the nanoparticles is referred to herein, the term relates to the average diameter of said nanoparticles.

Indium phosphide absorbs ultraviolet-visible-infrared light up to a spectral edge of approximately 750 nm. This permits a significant portion of the solar spectrum to be absorbed by the indium phosphide. In_{1-y}Zn_{y}P, where x is greater than 0 and less than or equal to 0.6, such as from 0.02 to 0.5 may have similar properties and may be used accordingly.

Any suitable absorption (or spectral) edge may be used in the invention (depending on the shell material(s)). A suitable absorption edge may be from 600 to 1000 nm, such as from 700 to 900 nm, such as about 750 nm in the core-shell nanoparticles disclosed herein. In embodiments of the invention, the absorption edge of from 600 to 1000 nm above may be derived from In₁₋ₓZnₓP (e.g. InP).

It will be appreciated that the photoluminescence peak and absorption edge will be selected to complement one another. As an example of a complementary pairing, the photoluminescence peak may be about 850 nm and the absorption edge may be about 750 nm. Further complementary pairings may be derived by the skilled person through their common knowledge.

In embodiments of the invention x and/or y may be 0.

In embodiments herein, the word “comprising” may be interpreted as requiring the features mentioned, but not limiting the presence of other features. Alternatively, the word “comprising” may also relate to the situation where only the components/features listed are intended to be present (e.g. the word “comprising” may be replaced by the phrases “consists of” or “consists essentially of”). It is explicitly contemplated that both the broader and narrower interpretations can be applied to all aspects and embodiments of the present invention. In other words, the word “comprising” and synonyms thereof may be replaced by the phrase “consisting of” or the phrase “consists essentially of” or synonyms thereof and vice versa.

Indium arsenide is a small bandgap III-V semiconductor that forms the core of the core-shell nanoparticle (which may also be referred to herein as a quantum dot), emitting at approximately 850 nm. An 850 nm emission wavelength is optimal for absorption by silicon solar cells. In₁₋ₓZnₓAs, where x is greater than 0 and less than or equal to 0.5, such as from 0.02 to 0.33 may have similar properties and may be used accordingly.

The molar ratio of In₁₋ₓZnₓAs (e.g. InAs) to In_{1-y}Zn_{y}P (e.g. InP) may be any suitable molar ratio, such as from 1:4 to 1:5000, such as from 1:10 to 1:1000, such as from 1:25 to 1:200 (e.g. 1:50). For the avoidance of doubt, when a number of values are provided herein in respect of a numerical range, these values may be combined in any way possible to provide further ranges that are specifically contemplated in the current application. Using the above values as an example, the following ranges are specifically contemplated:
from 1:4 to 1:5000, from 1:4 to 1:1000, from 1:4 to 1:200, from 1:4 to 1:50, from 1:4 to 1:25, from 1:4 to 1:10;
from 1:10 to 1:5000, from 1:10 to 1:1000, from 1:10 to 1:200, from 1:10 to 1:50, from 1:10 to 1:25;
from 1:25 to 1:5000, from 1:25 to 1:1000, from 1:25 to 1:200, from 1:25 to 1:50;
from 1:50 to 1:5000, from 1:50 to 1:1000, from 1:50 to 1:200;
from 1:200 to 1:5000, from 1:200 to 1:1000; and
from 1:1000 to 1:5000.

Unless otherwise specified, further ranges should be interpreted in the same manner.

In embodiments of the invention, the molar ratio of In₁₋ₓZnₓAs to In_{1-y}Zn_{y}P (e.g. InAs to InP) may be tuned to 1:50 in order to allow significant absorption by the In_{1-y}Zn_{y}P (e.g. InP), while Forster resonance energy transfer (FRET) within the quantum dot allows the emission to be dominated by InAs. This creates a sizable Stoke's shift of approximately 100 nm, therefore solving the reabsorption problem. Other molar ratios that also provide a similar Stoke's shift include those in which the In₁₋ₓZnₓAs to In_{1-y}Zn_{y}P (e.g. InAs to InP) molar ratio is less than 1:50, such as from 1:51 to 1:5000.

In embodiments of the invention, the nanoparticles may further comprise one or more of ZnSeS, ZnSe, and ZnS. When present, the molar ratio of Zn to Se, S or the combined total of Se and S may be from 0.1 to 1 to 10:1, such as 0.5 to 1 to 2:1, such as 1:1. In embodiments of the invention where ZnSeS, ZnSe, and ZnS is present, the molar ratio of In to Zn may be from 0.1 to 1 to 10:1, such as 0.5 to 1 to 2:1, such as 1:1, optionally wherein:
(a) when one of ZnSeS, ZnSe, and ZnS is present, the molar ratio of In to Zn may be from 0.1 to 1 to 10:1, such as 0.5 to 1 to 3:1, such as 2:1;
(b) when two of ZnSeS, ZnSe, and ZnS is present, the molar ratio of In to Zn may be from 0.1 to 1 to 10:1, such as 0.5 to 1 to 2:1, such as 1:1; or
(c) when all three of ZnSeS, ZnSe, and ZnS is present, the molar ratio of In to Zn may be from 0.1 to 1 to 10:1, such as 0.5 to 1 to 2:1, such as 1:2.

Examples of nanoparticles that may be disclosed herein are those that contain:
(a) InAs and InP;
(b) InAs, InP and ZnSe;
(c) InAs, InP and ZnS;
(d) InAs, InP, ZnSe and ZnS; or
(e) In_{1-y}Zn_{y}P and ZnSeS, where x is from 0.02 to 0.33 and y is from 0.02 to 0.5.

In embodiments of the invention, the molar ratio of to As may be from 5:1 to 1:1, such as 2:1. In additional or alternative embodiments of the invention, the molar ratio of In_{1-y}Zn_{y} to As may be from 5:1 to 1:1, such as 2:1.

As will be appreciated, the nanoparticles described hereinbefore may take any suitable form, such as nanoparticles that show a homogeneous distribution of the materials used in their manufacture or a heterogeneous distribution. In particular embodiments that may be disclosed herein, the nanoparticles may be core-shell nanoparticles.

Thus, there is disclosed herein core-shell luminescent nanoparticles comprising a core of In₁₋ₓZnₓAs and a shell layer of In_{1-y}Zn_{y}P surrounding the In₁₋ₓZnₓAs core; or
a core of In_{1-y}Zn_{y}P and a shell layer of In₁₋ₓZnₓAs surrounding the In_{1-y}Zn_{y}P core, wherein:
the molar ratio of In₁₋ₓZnₓAs to In_{1-y}Zn_{y}P is from 1:4 to 1:5000, such as from 1:10 to 1:1000, such as from 1:25 to 1:200 (e.g. 1:50)
x is from 0 to 0.5; and
y is from 0 to 0.6 (e.g. the core-shell nanoparticles may comprise a core of InAs and a shell layer of InP surrounding the InAs core, wherein the molar ratio InAs to InP is from 1:4 to 1:5000).

When used herein, the term “core-shell nanoparticle” refers to a nanoparticulate material that comprises a core portion at the centre of the particle and a shell portion surrounding and enclosing the core portion. The shell portion may comprise one or more layers of materials, with the first shell layer directly contacting the core portion and each subsequent shell layer directly surrounding and enclosing the previous shell layer and therefore also indirectly surrounding and enclosing the core portion and any other previous shell layers.

As will be appreciated, two possible arrangements of the central portion of the core-shell nanoparticle are contemplated.

The first is one in which the core-shell luminescent nanoparticles comprise:
a core of In₁₋ₓZnₓAs and a shell layer of In_{1-y}Zn_{y}P surrounding the In₁₋ₓZnₓAs core, wherein the molar ratio In₁₋ₓZnₓAs to In_{1-y}Zn_{y}P is from 1:4 to 1:5000, such as from 1:10 to 1:1000, such as from 1:25 to 1:200 (e.g. 1:50), wherein:
x is from 0 to 0.5; and
y is from 0 to 0.6.

In this arrangement, the emission is provided by the core material (In₁₋ₓZnₓAs or simply InAs if x is 0), with the adsorption edge being provided by at least the first shell layer (In_{1-y}Zn_{y}P or simply InP if y is 0).

In the above arrangement, In_{1-y}Zn_{y}P forms a shell layer around the In₁₋ₓZnₓAs core (e.g. as a first layer) and absorbs ultraviolet-visible-infrared light up to a spectral edge of approximately 750 nm. This permits a significant portion of the solar spectrum to be absorbed by the indium phosphide. In embodiments herein, the In_{1-y}Zn_{y}P layer may be in direct contact with the In₁₋ₓZnₓAs core or it may be spaced apart from the In₁₋ₓZnₓAs core by layers of other materials (e.g. ZnSe or ZnS). Preferably, the In_{1-y}Zn_{y}P layer is in direct contact with the In₁₋ₓZnₓAs core.

The second is one in which the core-shell luminescent nanoparticles comprise:
a core of In_{1-y}Zn_{y}P and a shell layer of In₁₋ₓZnₓAs surrounding the In_{1-y}Zn_{y}P core, wherein the molar ratio In₁₋ₓZnₓAs to In_{1-y}Zn_{y}P is from 1:4 to 1:5000, such as from 1:10 to 1:1000, such as from 1:25 to 1:200 (e.g. 1:50), wherein:
x is from 0 to 0.5; and
y is from 0 to 0.6.

In the above arrangement, In_{1-y}Zn_{y}P forms the core, surrounded by an In₁₋ₓZnₓAs shell (e.g. as a first layer), which may be described as an inverted type-I heterostructure. The In_{1-y}Zn_{y}P core absorbs ultraviolet-visible-infrared light up to a spectral edge of approximately 750 nm. This permits a significant portion of the solar spectrum to be absorbed by the indium phosphide (i.e. In_{1-y}Zn_{y}P). In embodiments herein, the In_{1-y}Zn_{y}P core may be in direct contact with the In₁₋ₓZnₓAs layer or it may be spaced apart from the In₁₋ₓZnₓAs layer by layers of other materials (e.g. ZnSe or ZnS). Preferably, the In_{1-y}Zn_{y}P core is in direct contact with the In₁₋ₓZnₓAs layer. In certain embodiments, the In₁₋ₓZnₓAs layer may have a photoluminescence peak of about 850 nm when the In_{1-y}Zn_{y}P has an absorption edge of about 750 nm.

In embodiments of both arrangements:
x may be from 0.02 to 0.33 or, more particularly, x may be 0; and/or
y may be from 0.02 to 0.5 or, more particularly, y may be 0.

The molar ratio of In₁₋ₓZnₓAs (e.g. InAs) to In_{1-y}Zn_{y}P (e.g. InP) in materials where In₁₋ₓZnₓAs forms the core portion of the composition may be any suitable molar ratio, such as from 1:4 to 1:5000, such as from 1:10 to 1:1000, such as from 1:25 to 1:200 (e.g. 1:50).

Similarly, the molar ratio of In_{1-y}Zn_{y}P (e.g. InP) to In₁₋ₓZnₓAs (e.g. InAs) in materials where In_{1-y}Zn_{y}P forms the core portion of the composition may be any suitable molar ratio, such as from 4:1 to 5000:1, such as from 10:1 to 1000:1, such as from 25:1 to 200:1 (e.g. 50:1).

In embodiments of the invention, the molar ratio of In₁₋ₓZnₓAs to In_{1-y}Zn_{y}P (e.g. InAs to InP) may be tuned to 1:50 in order to allow significant absorption by the In_{1-y}Zn_{y}P (e.g. InP) shell, while Forster resonance energy transfer (FRET) within the core-shell quantum dot allows the emission to be dominated by the InAs core. This creates a sizable Stoke's shift of approximately 100 nm, therefore solving the reabsorption problem. Other molar ratios that also provide a similar Stoke's shift include those in which the In₁₋ₓZnₓAs to In_{1-y}Zn_{y}P (e.g. InAs to InP) molar ratio is less than 1:50, such as from 1:51 to 1:5000.

The In₁₋ₓZnₓAs or In_{1-y}Zn_{y}P (e.g. InP or, more particularly, InAs) core portion may have any suitable diameter. Examples of suitable In₁₋ₓZnₓAs core diameters include, but are not limited to a diameter of from 10 to 50 Å, such as 15 to 25 Å, such as 20 Å. Examples of suitable In_{1-y}Zn_{y}P core diameters include, but are not limited to a diameter of from 30 to 110 Å, such as 50 to 90 Å, such as 70 Å.

In embodiments of the invention where In₁₋ₓZnₓAs is used as a core or as a shell layer, the molar ratio of to As may be from 5:1 to 1:1, such as 2:1. In additional or alternative embodiments, where In_{1-y}Zn_{y}P is used as a core or as a shell layer, the molar ratio of In_{1-y}Zn_{y} to As is from 5:1 to 1:1, such as 2:1.

As indicated above, in embodiments of the invention, the nanoparticles disclosed herein may also include one or more further shells selected from ZnSeS, ZnSe and ZnS. In particular embodiments of the invention, the further shells may be selected from ZnSe and/or ZnS. When used herein, the molar ratio of Zn to:
(i) Se;
(ii) S; or
(iii) Se and S combined,
   may be from 0.1 to 1 to 10:1, such as 0.5 to 1 to 2:1, such as 1:1. When Se and S are used together to form ZnSeS, the molar ratio of Se and S may be from 0.1 to 1 to 10:1, such as 0.5 to 1 to 2:1, such as 1:1.

When these shells are present, they may be located between the In_{1-y}Zn_{y}P (e.g. InP) shell layer and the In₁₋ₓZnₓAs (e.g. InAs) core or they may be located on top of the In_{1-y}Zn_{y}P layer, such that the In_{1-y}Zn_{y}P layer is in direct contact with the In₁₋ₓZnₓAs core. In particular embodiments of the invention, the ZnSeS, ZnSe and ZnS layers, when one or more are present, may be located on top of the In_{1-y}Zn_{y}P shell layer. Examples of particular arrangements of the nanoparticles disclosed herein include, but are not limited to:
(a) InAs/InP;
(b) InAs/InP/ZnSe;
(c) InAs/InP/ZnS;
(d) InAs/InP/ZnSe/ZnS; and
(e) In₁₋ₓZnₓAs/In_{1-y}Zn_{y}P/ZnSeS, where x is from 0.02 to 0.33 and y is from 0.02 to 0.5.

As will be appreciated, the nanoparticle arrangements described above disclose a core/first shell/second shell/third shell arrangement (where the second and third shells may or may not be present).

Zinc selenide (ZnSe) and zinc sulfide (ZnS) may be included as additional shells in order to passivate the quantum dot surface, reduce defects, and enhance their luminescence quantum efficiency. Zinc selenide sulfide (ZnSeS) may be used for similar reasons.

InAs, InP, ZnSe and ZnS possess a decreasing lattice spacing of 6.06 Å, 5.87 Å, 5.67 Å and 5.42 Å, respectively, hence allowing the strain caused by lattice mismatch to be gradually relaxed across the layers. Another significant advantage in the use of this set of materials lies in their ability to absorb across the entire visible spectrum and to emit in the infrared, hence allowing the creation of neutral-coloured LSCs. This is critical for wide-scale adoption of this technology, as other luminescent materials are typically too colourful, and produce a visible glow from their light emission, hence limiting their applications to niche areas. Similar lattice spacings are obtained when In₁₋ₓZnₓAs, In_{1-y}Zn_{y}P and ZnSeS are used to substitute one or more of InAs, InP, ZnSe and ZnS as the case may be.

In embodiments of the invention, the nanoparticles may have a photoluminescence peak and an absorption edge, where the photoluminescence peak may be red-shifted from 50 to 250 nm, such as 75 to 150 nm away, such as 100 nm away from the absorption edge. In certain embodiments of the invention, the photoluminescence peak may be from 700 to 1100 nm and/or the absorption edge may be from 600 to 1000 nm. In further embodiments, the photoluminescence peak may be from 800 to 1000 nm and/or the absorption edge may be from 600 to 1000 nm, such as from 700 to 900 nm.

The nanoparticles disclosed herein may be formed by any suitable method.

For example, the method may be a method of forming a luminescent nanoparticle, which method comprises providing a core of In₁₋ₓZnₓAs and forming a first shell of In_{1-y}Zn_{y}P on the In₁₋ₓZnₓAs core, wherein the molar ratio of In₁₋ₓZnₓAs to In_{1-y}Zn_{y}P is from 1:4 to 1:5000, such as from 1:10 to 1:1000, such as from 1:25 to 1:200 (e.g. 1:50), where: x is from 0 to 0.5, such as from 0.02 to 0.33; and y is from 0 to 0.6, such as from 0.02 to 0.5. In particular embodiments, the method may be a method of forming a core-shell luminescent nanoparticle, which method comprises providing a core of InAs and forming a first shell of InP on the InAs core, wherein the molar ratio InAs to InP is from 1:4 to 1:5000, such as from 1:10 to 1:1000, such as from 1:25 to 1:200 (e.g. 1:50).

Alternatively, the method may be a method of forming a core-shell luminescent nanoparticle, which method comprises providing a core of In_{1-y}Zn_{y}P and forming a first shell of In₁₋ₓZnₓAs on the In_{1-y}Zn_{y}P core, wherein the molar ratio of In₁₋ₓZnₓAs to In_{1-y}Zn_{y}P is from 1:4 to 1:5000, such as from 1:10 to 1:1000, such as from 1:25 to 1:200 (e.g. 1:50), where: x is from 0 to 0.5, such as from 0.02 to 0.33; and y is from 0 to 0.6, such as from 0.02 to 0.5.

As will be appreciated, the nanoparticles disclosed herein may further contain two to three shells. Therefore, the method(s) may further comprise one of the following additional process steps:
(a) forming a second shell around the first shell, where the second shell is formed from ZnSeS or, more particularly, ZnSe or ZnS;
(b) forming a second shell around the first shell, where the second shell is formed from ZnSe and forming a third shell around the second shell, where the third shell is formed from ZnS;
(c) forming a second shell around the first shell, where the second shell is formed from ZnS and forming a third shell around the second shell, where the third shell is formed from ZnSe;
(d) forming a second shell around the first shell, where the second shell is formed from ZnSeS and forming a third shell around the second shell, where the third shell is formed from ZnS;
(e) forming a second shell around the first shell, where the second shell is formed from ZnS and forming a third shell around the second shell, where the third shell is formed from ZnSeS;
(f) forming a second shell around the first shell, where the second shell is formed from ZnSeS and forming a third shell around the second shell, where the third shell is formed from ZnSe; or
(g) forming a second shell around the first shell, where the second shell is formed from ZnSe and forming a third shell around the second shell, where the third shell is formed from ZnSeS.

Particular embodiments of the method that may be mentioned herein are those making use of (a) to (c) above.

The resulting products of the methods outlines above may have (e.g. have) the same physical and chemical properties disclosed hereinbefore in relation to the nanoparticles per se.

While the method described above is intended to relate to the formation of core-shell nanoparticles, it may also be useful for the formation of nanoparticles having a homogeneous distribution of the component materials (or other heterogeneous arrangements of the component materials).

Further details concerning the manufacture of the nanoparticles disclosed herein are provided in the experimental section below.

The nanoparticles described hereinbefore may be dispersed within a suitable polymeric material to form a composite material that may have a range of uses. Thus, there is also disclosed a composite material comprising:
a luminescent nanoparticle (e.g. a core-shell luminescent nanoparticle) material as described above; and
a polymeric material, wherein the luminescent nanoparticle material is homogeneously dispersed throughout a matrix formed by the polymeric material.

As will be appreciated, the nanoparticles described in this composite material may be any of those described above.

Without wishing to be bound by theory, it is believed that the quantum dots need to be individually-dispersed in a polymer matrix to prevent photoluminescence quenching caused by energy transfer and to provide additional protection against material degradation. The dispersion of the nanoparticles disclosed herein in a polymer matrix can be achieved by a photo-curing or thermal curing approach. To obtain spatial separation, the quantum dots may be first mixed into a purified vinyl monomer such as methyl methacrylate (MMA) to form a dispersion. The dispersion can then be, optionally, pre-cured with light to form polymer shells around the nanocrystals. A vinyl-terminated oligomer is mixed into the dispersion to tune the viscosity, promote crosslinking and increase the speed of photo-curing (or thermal curing). A photo-initiator (or thermal initiator) may be added to the mixture and this will form radicals and initiate polymerization when illuminated with UV light (or when heated). The dispersion should be viscous but clear, and should have no signs of aggregation. This dispersion “ink” should fully-polymerize and crosslink within a few seconds of UV light exposure (or heating) to form a composite comprising individually-dispersed quantum dots in a polymer matrix. As will be appreciated, the dispersion may be used as-is and fully cured in situ in some applications, as explained below.

There are several advantages associated with the above-described approach. First, the vinyl monomers will fully react and the dispersion requires no extra solvents. There is therefore no need for expensive solvent treatment and removal in the manufacturing process. The viscous solution can be pre-tuned and optimised to ensure good clarity and no haze in the final product. The fast photo-curing (or thermal-curing) approach could ensure that the quantum dots remain dispersed in the polymer matrix, in contrast to aggregation seen in typical polymer blends. The pre-curing step could also help in keeping the quantum dots spatially-separated, and may improve PL performance, stability and film clarity.

Any suitable polymeric material may be used to provide the matrix material. As will be appreciated, it would be advantageous if the polymeric material selected is one that does not absorb (or minimally absorbs) solar light. Examples of suitable polymeric materials include, but are not limited to a vinyl polymer or a vinyl copolymer. When used herein, the term “vinyl” or “vinyl group” is intended to refer to the functional group “H₂C═CH—”. Examples of such vinyl polymers that may be mentioned herein include, but are not limited to polystyrenes and polyacrylate esters (and their copolymers). When used herein “polyacrylate ester” is intended to refer to polymeric compounds where the carboxylic acid group is presented in the form of an ester, such as, but not limited to, methyl methacrylate, lauryl methacrylate and isobornyl acrylate. As will be appreciated, the polystyrenes used herein may be formed using styrene as the monomer, as may any suitable monomeric derivative of styrene (e.g. where the phenyl ring is substituted by a C₁₋₆ alkyl group or a halo group), or one or more styrenes may be used. For the avoidance of doubt, the polymeric materials disclosed herein may be homopolymers or copolymers. When the polymeric material is a copolymer, any suitable combination of styrenes and acrylates is contemplated. For example, the copolymer may comprise: two or more styrenes; two or more acrylates; or at least one styrene and at least one acrylate. In addition, the polymeric matrix material may be formed of a blend of two or more of the above-mentioned materials. In particular embodiments of the invention, the polymer (i.e. homopolymer) may be polymethylmethacrylate or polystyrene and the copolymer may be formed from methyl methacrylate or styrene and an oligomer having vinyl terminal groups. When used herein, the oligomer may be an oligomeric material formed from any of the materials discussed hereinbefore, provided that it does not result in the formation of a homopolymeric material.

In embodiments of the invention that may be disclosed herein, the polymeric material may be poly(methyl methacrylate) (PMMA). However, as noted above, other polymeric materials may be used, such as polystyrene or other vinyl-derived polymers or copolymers of the kind described above.

In certain embodiments of the invention, nanoparticles that comprise InP, but not InAs, may be added to the composition. Examples of such materials include: InP and ZnSeS; or, more particularly, InP, ZnSe and ZnS; InP and ZnSe; and InP and ZnS. These nanoparticle may have a diameter of from 2 nm to 100 nm.

In certain embodiments of the invention, InP core-shell nanoparticles (where InP is the core and which do not contain InAs) may be added to the polymeric matrix. Such InP core-shell nanoparticles may be nanoparticles selected from the group consisting of InP/ZnSe/ZnS, InP/ZnSe and InP/ZnS and these may have the diameter of the InP core-shell nanoparticles is from 2 nm to 100 nm. The InP core-shell nanoparticles may be prepared by analogy to the methods used to manufacture the InAs and InP/InAs core-shell nanoparticles disclosed in the experimental section hereinbelow.

As will be appreciated, the composite material (comprising the luminescent nanoparticles) disclosed herein may be particularly suitable for use in the formation of luminescent solar concentrators (LSCs) and so there is disclosed herein a use of a core-shell nanoparticle material or a composite material as described herein as a solar concentrator. Thus, there is also disclosed herein a luminescent solar concentrator comprising a layered material having at least one edge, wherein the layered material comprises at least one layer of a composite material as described above sandwiched between at least two transparent substrate layers.

For the sake of brevity, the nanoparticles referred to in the description below will be those having a core of InAs and at least a shell layer of InP. It will be appreciated that the discussion below also applies to all of the other nanoparticles that form part of the current disclosure as well (i.e. to nanoparticles having homogeneous distribution of components, as well as core-shell nanoparticles having a core of In₁₋ₓZnₓAs and at least a shell layer of In_{1-y}Zn_{y}P and to core-shell nanoparticles having a core of In_{1-y}Zn_{y}P and at least a shell layer of In₁₋ₓZnₓAs).

Any suitable transparent material may be used to provide the two substrate layers. Examples of suitable materials that may be used as the at least two (e.g. 2, 3, 4, 5, 6) transparent substrate layers include, but are not limited to glass, a polymeric material and combinations thereof. As will be appreciated, one of the substrate layers may be glass, while a second layer may be made from a polymeric material and all suitable combinations are contemplated. When used herein the term “transparent material” will be understood to mean a material that has a transmittance value of greater than or equal to 90% and a haze value of less than or equal to 5%.

The LSC comprises at least two substrate materials that sandwich the composite material (that contains the luminescent nanoparticles). As such, there is at least a first substrate that provides a first exposed surface and a second substrate that provides a second exposed surface. These exposed surfaces are separated by the combined thickness of the substrates and the thickness of the composite material, the resulting thickness forming the at least one edge. This may also be referred to herein as the at least one working edge of the LSC, as it is the edge through which the concentrated light is intended to pass through for further use. As will be appreciated, the number of edges that are provided by the LSC depends on how the LSC is formed. For example, if the LSC is formed in the shape of a circle, then there is effectively only a single edge. If the LSC is formed in the shape of a rectangle or square, then there will be four edges, for a hexagon, there will be sixe edges etc. There is no limit on the number of edges that may be present in a LSC according to the current invention, other than practical considerations for the production of energy from said LSC.

As will be appreciated, the LSC operates because of the presence of luminescent particles. These luminescent particles can absorb and concentrate the incoming light in the polymeric material that they are present in. The absorbed energy can then be emitted (e.g. at a longer wavelength near the infrared spectrum), and any remaining energy may be released as heat by a thermalization process. The emitted light travels through the polymeric material (or waveguide), being reflected by total internal reflection (TIR) or re-absorbed by other particles and emitted again. Some of the light reflected may be lost by transmission through the two exposed surfaces of the substrates as well. The remaining light that reaches the edge of the LSC may be absorbed by a solar cell (e.g. a photovoltaic cell) or reflected by mirrors (e.g. towards a solar cell or for direct use). LSCs of the current invention may have any suitable level of transmittance to the at least one edge of the concentrator. For example, the average transmittance of the concentrator may be from 5 to 95%, such as from 20 to 80%.

A solar window (or LSC) needs to be made of glass (or a durable transparent polymeric material) to withstand weathering and to provide structural strength. As noted above, the composite material of the luminescent quantum dots and polymer matrix can be sandwiched and encapsulated between two panels of glass (or polymer), or are adhered as a composite film to one side of a glass panel to form the solar window. The glass panel serves to protect the quantum dot layer from moisture or oxygen induced degradation. This solar window, in addition to light absorption and energy generation, will also have the advantage of improved safety performance and break resistance due to the use of a glass-polymer layered structure. This is ideal for applications in building windows and facades and in automobile windows.

There are three main approaches towards achieving a LSC structure:

### Coating Approach

The dispersion of quantum dots in a polymer may be coated evenly onto a cleaned glass panel at a desired thickness using a roll-to-roll technique (e.g. slot-die coating). Another cleaned glass (or polymer substrate) is placed above the coating and a mild vacuum is applied to remove trapped air bubbles (vacuum should be weak to prevent vaporizing the monomer). The entire stack is illuminated (or heated) to trigger polymerization and crosslinking. The entire panel should cure within a minute.

The curing of polymer, in direct contact with the two panels, is a more straightforward approach and will ensure good adhesion across the entire stack. The flow of the dispersion under uneven pressure may, however, cause uneven coating, and this may be solved to a certain extent by using a more viscous dispersion.

### Lamination Approach

The above-formulated dispersion may be coated evenly onto a thin polymer substrate (e.g. MMA) in a roll-to-roll fashion (e.g. slot-die coating). The coated film is photo-cured (or thermally cured) immediately to form a clear and dry film. Multiple coating passes could be used if thicker layers are desired. The film may then be sandwiched between two EVA/PVB/POE sheets and two glass panels. The entire stack may be placed into a vacuum oven at 150° C. for lamination. Lamination should be completed in approximately 10 minutes to prevent material degradation.

There are several advantages associated with lamination approach. The quantum dots embedded film can be separately manufactured using a roll-to-roll process, hence allowing this film to be sold as product, and allows more versatile use in different products. The use of a solid film ensures good control of uniformity and thickness since there is no problem with viscous flow. The solid film could be first inspected for uniformity and quality, hence increasing yield of end product. However, the high temperature that is needed for lamination of the polymer sheets could potentially cause material degradation.

### Sticker Film Approach

The above-formulated dispersion may be coated evenly onto a barrier film substrate with low oxygen and moisture penetration. The coated film may then covered with another barrier film, and the stack photo-cured (or thermally cured) immediately to form a luminescent quantum dot sheet. This quantum dot sheet may then be coated with an optically-clear adhesive such that it can be easily pasted or removed from glass panels.

This approach offers versatility in the implementation of the luminescent film layer, without requiring a complete replacement of the glass panel. The colour, transmittance, performance of the LSC could be easily changed by replacing the luminescent film layer at reasonably low cost, without affecting the rest of the glass or solar cell structure. In addition, the lifespan of the glass and silicon solar cells are likely to outlast the luminescent film layer. Hence, it would be beneficial to allow the replacement of luminescent film once every 5 to 10 years after the performance has degraded, or when newer technology that offers better performance becomes available. The luminescent films could be designed and printed into various patterns, shapes or words, and serve to enhance the aesthetics of the solar window. The films could also be easily removed if the user decided to increase light transmittance across the window.

Solar illumination is absorbed by the luminescent quantum dots at wavelengths below 750 nm, primarily by InP. The photon energy is then down-converted and re-emitted at ˜850 nm by InAs. Up to 75% of this re-emitted light can be trapped within the glass panel by total internal reflection, and is wave-guided towards the panel edges, thereby achieving solar concentration. Thin strips of silicon solar cells can be lined across the panel edges to absorb the 850 nm light and convert that into electrical power. Thus, the LSC may further comprise one or more solar cells arranged along at least one edge of the layered material. For example, the at least one edge of the layered material may be substantially covered by solar cells. This may allow for the most efficient receipt of the transmitted light for transformation into a suitable form of energy for use (e.g. electrical energy).

A typical laminated glass construction for LSCs described herein may comprise two 3 mm glass panels and a 0.38 mm polymer interlayer (the polymer composite material). Hence, silicon collar cells that are cut into 6-8 mm widths may be ideal for lining the panel edges of such a construction.

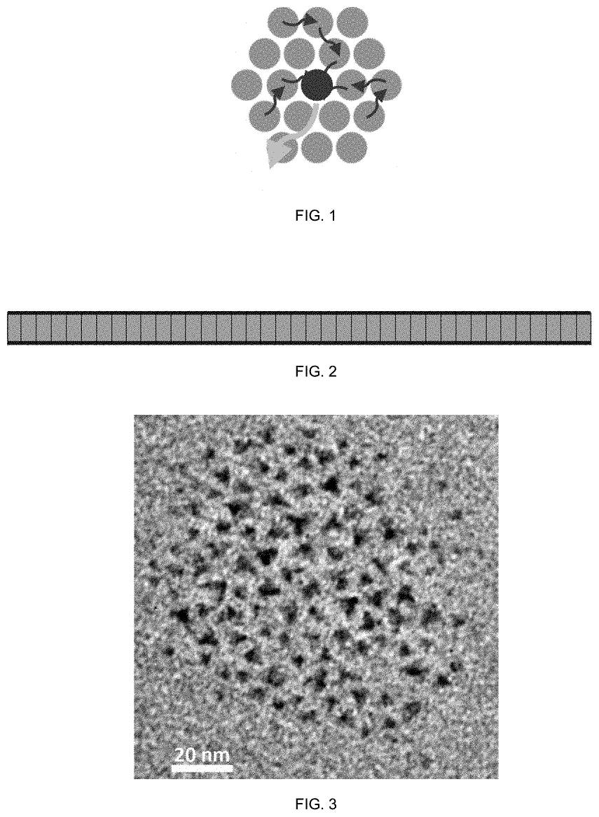

In order to arrange the solar cells efficiently (or mirrors etc), one or more busbars (e.g. 1, 2, 3, 4, 5, 6, 7, 8, 9, 10) may be attached to the solar cell(s) in a manner that does not block the at least one edge of the layered material. For example, the silicon strips (silicon collar cells) may be 2 mm wider than the panel thickness, and the extra 1 mm along each side are covered by a 1 mm thick busbar. Thinner fingers are distributed at 1.5 mm intervals across the strip, connecting to the two busbars at the edges (see FIG. 2). This design will ensure that all the light that is collected at the glass panel edge is not be blocked by the thick busbars. The two thick busbars would also ensure minimal series resistance and effective current collection.

For effective transmittance of light from the glass panel edge to the solar cell strips, the solar cells may be adhered to the panel edge using an index-matching adhesive. A transparent and solvent-less epoxy adhesive or acrylate adhesive is suitable for this application. In a typical design, the solar cell strips may be first aligned, connected in series and then assembled into the structural frame of the solar glass panel. The adhesive may be liberally applied into the structural frame, followed by assembly with the solar glass panel to complete the fabrication of the LSC. The adhesive also serves to encapsulate the silicon solar cells and all optical and electrical components, and is therefore very important towards prolonging the lifespan of the LSC device.

It is worth noting that clear glass windows may be fitted with solar cell strips along the edges, making them “solar-ready” windows. The luminescent films may then be adhered to the glass surface, using the above-described sticker approach, to convert them into proper LSC windows.

The distribution of light along the panel edge would differ based on the size and shape of the glass panel. Since the solar cells along the panel edges are connected in series, they need to be current-matched to achieve optimum power conversion efficiencies. The approach towards current matching would involve placing cells of different lengths along the panel edge, such that the integrated light intensity across each cell is equal. Generally, the centre should receive more light, while the corners receive less.

A computational model that calculates light intensity as a function of panel size, shape, aspect ratio, light reabsorption, light scattering, photon wavelength has been developed, and the lengths of the solar cells can be designed accordingly based on simulations. Since the centre of the panel edge receives more light compared to the corners, the solar cells in the centre will be shorter compared to the solar cells at the corners in the cases where current-matching is required. As will be appreciated, similar computational models may be developed and used by a skilled person knowledgeable in this field.

Luminescent solar concentrators should, in practice, be very large panels for installation in windows and building facades. We have constructed prototypes using low-iron glass with a size of 100 cm by 100 cm by 0.5 cm (see examples below). The glass was purchased commercially through external suppliers while the luminescent materials, such as the quantum dots embedded in polymer matrix, are synthesised and subsequently coated on top of the glass. Since the prototype can be lined on all four sides with solar cells, this represents a geometric gain of 50 times. The LSC panel has an average visible transmittance of 25%. Theoretically, assuming 75% light absorption, 60% photoluminescence quantum yield, 60% light-trapping and wave-guiding, and a 20% silicon solar cell efficiency, it is believed that an overall solar-to-electric power conversion efficiency of 5.4% can be ideally obtained from the LSC panels disclosed herein. It is worth noting that our panel size and power conversion efficiency is unprecedented for transparent solar modules, and is larger than most window panels used in standard households.

It is believed that this technology will see significant application in building-integrated photovoltaics (BIPV) and in transportation vehicles. Examples of suitable locations include transparent rooftop gardens, bus stations, glass buildings, household windows and along train tracks.

Further aspects and embodiments of the invention are provided by the following non-limiting examples.

### EXAMPLES

### Example 1

### Luminescent Quantum Dots Synthesis

In this example, luminescent quantum dots comprising InAs, InP, ZnSe and ZnS were sequentially grown in one-pot to form a multi-core-shell structure. In this synthesis, the overall quantum dot size was approximately 10 nm in diameter. The InAs core consists of a cluster of 20 unit cells (20.4 Å diameter), the InP shell has 1000 unit cells (73.4 Å diameter), the ZnSe shell has 1000 unit cells (90.6 Å diameter) and the ZnS shell has 1000 unit cells (101.5 Å diameter). Since the InP shell is substantially larger than the InAs core, the InP will absorb most of the radiation, while transferring the energy to InAs for light emission.

The entire quantum dot synthesis process takes 6 hours.

### 1.1 Solvent/Reactant/Reagent Preparation

1-octadecene (ODE, 40 mL) and octylamine (2 mL), in two separate round-bottom flasks (RBF), were dried with activated molecular sieves and degassed under vacuum for 30 minutes. The RBFs were filled with argon, and the ODE and octylamine were ready for use in subsequent experiments.

### 1.2 InAs Core Synthesis

Indium acetate (0.08 mmol) and myristic acid (0.3 mmol) were mixed with ODE (4 mL; as prepared above in 1.1) in an argon-filled 100 mL RBF. Vacuum was applied to the RBF and the mixture was heated to 60° C. for 30 minutes under vacuum. The mixture was then heated to 190° C. and stirred for 15 minutes to form a clear solution (indium precursor solution).

Trimethylsilylarsine (TMSi)₃As (0.04 mmol) and octylamine (0.08 mL; as prepared above in 1.1) were mixed with ODE (1 mL; as prepared above in 1.1) under argon in a glovebox. The resulting arsine solution was injected into the indium precursor solution dropwise, which was still at a temperature of 190° C. The resulting mixture was allowed to stir at 190° C. for 20 minutes to consume all precursors and complete the InAs core synthesis. 4 mL of the reaction mixture was transferred out for storage, leaving 1 mL of the reaction mixture in the RBF. This reaction mixture is referred to below as the InAs core solution. It is believed that the temperature and reaction time mentioned above are optimised to provide an InAs core that emits at ˜850 nm.

### 1.3 InP Shell Synthesis

In a separate RBF, indium acetate (0.8 mmol) and myristic acid (3 mmol) were mixed with ODE (8 mL; as prepared above in 1.1). Vacuum was applied to the RBF and the mixture was heated to 60° C. for 30 minutes under vacuum. The mixture was then heated to 120° C. and stirred for 15 minutes to form a clear solution (indium precursor solution).

Trimethylsilylphosphine (TMSi)₃P (0.4 mmol) and octylamine (0.8 mL) were mixed with ODE (8 mL) under argon in a glovebox to provide a phosphine precursor solution.

The InAs core solution (1 mL; as prepared above in 1.2) was heated to 190° C. and the indium precursor solution and phosphine precursor solution were injected dropwise into the heated InAs core solution over 8 intervals at a rate of 1 mL every 15 min interval. The first 2 injections were performed with the core solution/reaction mixture at 190° C., the next 3 injections were performed with the reaction mixture at 200° C., and the last 3 injections were performed with the reaction mixture at 210° C. Aliquots (50 μL) of reaction mixture were extracted to monitor reaction progress by spectroscopy after every 15 min interval. After complete injection, the solution was stirred for another 60 minutes at 210° C. to expend all precursors and complete the InP shell synthesis.

The resulting InAs/InP core-shell solution was heated to 220° C. for subsequent shell growth reactions, as described below.

It is believed that the temperature and reaction time are optimised for InP shell to absorb up to ˜750 nm. It is also believed that the multiple injections of the precursors that for the InP shell keeps precursor concentration low at all times to prevent new nucleation events, and thereby promotes the growth of an InP shell on existing quantum dots in the core solution/reaction mixture.

### 1.4 ZnSe/ZnS Shell Synthesis

Selenium (0.4 mmol), trioctylphosphine (TOP, 0.4 mmol) and ODE (4 mL; as prepared above) were mixed and sonicated in a RBF at 120° C. for 30 minutes in an argon atmosphere to prepare a TOP-Se precursor.

Sulfur (0.4 mmol), TOP (0.4 mmol) and ODE (4 mL; as prepared above) were mixed and sonicated in a RBF at 120° C. for 30 minutes in an argon atmosphere to prepare TOP-S precursor.

Zinc stearate (0.8 mmol) and ODE (8 mL; as prepared above) were mixed and stirred in a RBF for 30 minutes at 120° C. in an argon atmosphere to form a clear zinc precursor solution.

All precursor solutions were degassed under vacuum at 60° C. for 30 minutes.

The zinc precursor (4 mL) and TOP-Se precursor (4 mL) was injected into the InAs/InP core-shell (held at 220° C.—see 1.3 above) dropwise and the reaction mixture was stirred for 30 minutes to expend all precursors and complete the ZnSe shell.

The zinc precursor (4 mL) and TOP-S precursor (4 mL) was injected into the InAs/InP/ZnSe core-shell solution (held at 220° C.) dropwise and the reaction mixture was stirred for 30 minutes to expend all precursors and complete the ZnS shell. Thereby providing an InAs/InP/ZnSe/ZnS core-shell solution.

It is believed that the temperature and reaction times for these steps are optimised for maximum PL quantum yield.

### 1.5 Workup and Purification

The InAs/InP/ZnSe/ZnS core-shell solution was allowed to cool to room temperature. Ethanol (50 mL) was added to the reaction mixture to precipitate the InAs/InP/ZnSe/ZnS quantum dots, followed by centrifugation of the mixture at 10,000 rpm for 10 minutes. The clear supernatant was carefully removed using a dropper. Another 50 mL of ethanol was added and mixed with the black precipitate layer, followed by another round of centrifugation. The precipitate was re-dispersed in hexane (20 mL) and the dispersion was centrifuged at 5,000 rpm for 5 minutes. The supernatant was collected and stored for future use.

As will be appreciated, the synthesis of InAs/InP, InAs/InP/ZnSe, InAs/InP/ZnS, and other variants may be formulated based upon the synthetic conditions provided above.

### Results

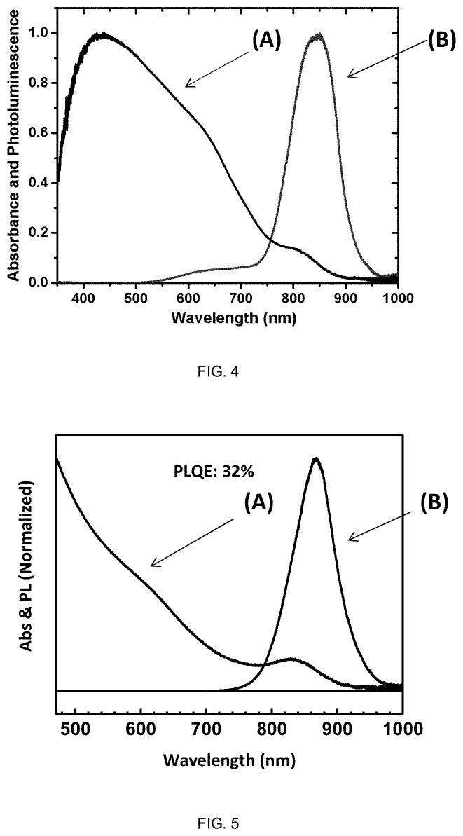

The transmission electron microscope image in FIG. 3 shows a sample of InAs/InP/ZnSe/ZnS quantum dots. The quantum dots are approximately 8-10 nm in size and are irregularly shaped. The absorbance and photoluminescence spectra of an InAs/InP/ZnSe/ZnS quantum dot solution sample is shown in FIG. 4. The tiny absorption shoulder between 750 and 850 nm belongs to the InAs core. The primary absorption edge lies at around 750 nm, and is contributed by the InP shell. The photoluminescence spectrum of the InAs core is centered at 850 nm, and has a respectable quantum yield of 40%. This result shows that a multi-core-shell InAs/InP/ZnSe/ZnS with a large Stoke's shift of ˜100 nm (between primary absorption edge and emission peak) is formed by the process above.

A weak photoluminescence shoulder from 550 to 750 nm belongs to a small proportion of InP quantum dots without an InAs core. Optimization of the quantum dot synthesis protocol is expected to lead to both a smaller absorption and photoluminescence shoulder.

### Example 2

Luminescent Quantum Dots Synthesis with Continuous Injection Methodology

### 2.1 In(Zn)As Core Synthesis

Indium acetate (0.10 mmol, 30 mg), zinc acetate (0.05 mmol, 10 mg) and oleic acid (0.0375 mmol, 13.2 μl) were mixed with ODE (5 mL; as prepared in 1.1) in an argon-filled 100 mL RBF. Vacuum was applied to the RBF and the mixture was heated to 80° C. for 30 minutes under vacuum. The mixture was then heated to 160° C. and stirred for 1 hour in argon to form a clear solution. The mixture was cooled to 80° C. and then vacuumed for 30 minutes at 80° C. The RBF was then filled with argon and heated to 230° C. to give an indium precursor solution.

TMS₃As (0.066 mmol, 20 μl) and octylamine (0.20 mL; as prepared in 1.1) were mixed with ODE (to make 1 mL) under an inert argon glovebox environment. The resulting arsine solution was injected into the indium precursor solution (prepared above; which was still kept at 230° C.) dropwise over 5 seconds. The resulting mixture was allowed to stir at 230° C. for 2.5 hours to expand all precursors and complete the In(Zn)As core synthesis, with a final resulting volume of 5 mL. Upon completion of the core synthesis, the RBF was air-cooled to room temperature and 0.37 mL (0.005 mmol) of the In(Zn)As core reaction mixture was transferred to another argon-filled 100 mL RBF with dried ODE (2.5 mL; as prepared in 1.1). The new RBF (“In(Zn)As reaction mixture”) was heated to 230° C. for subsequent In(Zn)P shell synthesis. This reaction mixture is referred to below as the In(Zn)As core solution. It is believed that the temperature and reaction time mentioned above are optimised to provide an In(Zn)As core that emits at ˜690 nm.

### 2.2 In(Zn)P Shell Synthesis

In a separate RBF, indium acetate (0.25 mmol, 73 mg), zinc acetate (0.25 mmol, 46 mg) and oleic acid (1.875 mmol, 0.67 mL) were mixed with ODE (to make 9 mL; as prepared in 1.1). Vacuum was applied to the RBF and the mixture was heated to 80° C. for 30 minutes under vacuum. The mixture was heated to 160° C. and stirred for 1 hour in argon to form a clear solution. The mixture was subsequently cooled to room temperature and vacuumed for 30 minutes to give a indium precursor solution.

TMS₃P (0.25 mmol, 73 μl) and octylamine (0.5 mL) were mixed with ODE (to make 1 mL; as prepared in 1.1) under an inert argon glovebox environment. The resulting phosphine precursor solution was injected into the indium precursor solution at room temperature over 5 seconds and mixed for 15 minutes to form the indium phosphide precursor solution.

The indium phosphide precursor solution was injected into the In(Zn)As reaction mixture (as prepared in 2.1; which was still kept at 230° C.) using a syringe pump, at a rate of 0.1 mL/min. The temperature was raised to 240° C. after 33 minutes (from the start of injection), and to 250° C. after 66 minutes (from the start of injection). After complete injection at 100 minutes, the temperature was raised to 260° C. and the solution was stirred for another 30 minutes to expand all precursors and complete the In(Zn)P shell synthesis.

The resulting In(Zn)As/In(Zn)P core-shell solution was heated to 260° C. for subsequent shell growth reactions, as described below. The resulting core-shell solution in this example has a molecular formulae of Inₓ(Zn₁₋ₓ)As for the core and In_{y}(Zn_{1-y})P for the shell, where x is from 0.6 to 1 and y is from 0.5 to 1.

It is believed that the temperature and reaction time are optimised for In(Zn)P shell to absorb up to ˜750 nm. It is also believed that continuous injections of the precursors for the In(Zn)P shell keeps precursor concentration low at all times to prevent new nucleation events, and thereby promotes the growth of an InP shell on existing quantum dots in the core solution/reaction mixture.

### 2.3 ZnSeS Shell Synthesis

Sulfur (0.50 mmol, 16 mg), Selenium (0.50 mmol, 39 mg) and TOP (1 mmol, 0.45 mL) was mixed with ODE (to make 10 mL; as prepared in 1.1) in a RBF at 80° C. for 30 minutes in an argon atmosphere to prepare TOP—S—Se precursor. The TOP—S—Se precursor solution was degassed at 80° C. for 2 hours under vacuum.

Zinc acetate (1 mmol, 183 mg) and oleic acid (2.5 mmol, 0.88 mL) were mixed with ODE (to make 10 mL; as prepared in 1.1) in a RBF. Vacuum was applied to the RBF and the mixture was heated to 80° C. for 30 minutes under vacuum. The zinc precursor solution was heated to 160° C. and stirred for 1 hour in argon to form a clear zinc precursor solution.

The TOP—Se—S precursor solution (10 mL) and the zinc precursor solution (10 mL) were simultaneously injected into the In(Zn)As/In(Zn)P core-shell (held at 260° C.; as prepared in 2.2 above) using a syringe pump with two injection channels at a rate of 0.1 mL/min. After complete injection at 100 minutes, the reaction mixture was stirred for another 25 minutes at 260° C. to expand all precursors and complete the ZnSeS shell.

It is believed that the temperature and reaction times for these steps are optimised for maximum PL quantum yield.

### 2.4 Workup and Purification

The In(Zn)As/In(Zn)P/ZnSeS core-shell solution was allowed to cool to room temperature. Ethanol (50 mL) was added to the reaction mixture to precipitate the In(Zn)As/In(Zn)P/ZnSeS quantum dots, followed by centrifugation of the mixture at 6000 rpm for 5 minutes. The clear supernatant was carefully removed using a dropper. The addition of ethanol and centrifugation were repeated for two more times. The precipitate was re-dispersed in hexane (20 mL).

### Results

FIG. 5 shows the absorbance and photoluminescence of an In(Zn)As/In(Zn)P/ZnSeS quantum dot solution. The quantum dots absorb strongly across the entire visible light region up to 750 nm and emit fluorescence at 870 nm with PLQE of 32%.

### Example 3

Dispersion of Quantum Dots into a Polymer Precursor Solution and Fabrication of Thin Film

### 3.1 Materials

The quantum dots solution was obtained through methods mentioned in Examples 1 and 2 above. The solution was degassed with argon for around 10 minutes. Afterwards, trioctylphosphine (TOP, 97% purity, Sigma Aldrich) was injected into the solution (0.05 mL per 1 mL of quantum dots solution). The final solution was stirred for at least two hours and subsequently ready for use. Isobornyl acrylate (technical grade), tricyclo[5.2.1.02,6]decanedimethanol diacrylate (99% purity), and 2,2-Dimethoxy-2-phenylacetophenone (DMPA, 99% purity) were purchased from Sigma Aldrich and used as received. Polyethylene terephthalate (PET, Toyobo A4200) film was used as received. Transparent borosilicate glass was purchased from Shenyang Yibeite Optics and used as received.

### 3.2 Pre-Polymerisation of Resin

Isobornyl acrylate was mixed with 0.25 wt % DMPA. The mixture was degassed with argon for 10 minutes and then photo-polymerised with UV lamp (365 nm, 46 W) for 30 seconds.

### 3.3 Quantum Dots-Polymer Composite Film

To prepare a 16×16 cm² film of 200 μm thickness, 15 mL of quantum dots solution (20 mg/mL in hexane and TOP) was centrifuged with ethanol to remove the solvent. The solution was redispersed with 500 μL of isobornyl acrylate and stirred for at least 10 minutes until a homogenous solution was formed. 5 mL of pre-polymerised isobornyl acrylate (viscosity around cP 1000; as prepared in 3.2) was mixed into the solution and stirred further for at least 10 minutes. 2.3 mL of tricyclo[5.2.1.02,6]decanedimethanol diacrylate was added to the solution and stirred for at least 10 minutes. Finally 37.5 mg of DMPA (0.47 wt %) was added and the overall mixture was stirred for at least 1 hour. The resulting resin composite was then coated in between 16×16 cm² glass and PET barrier film using an adjustable film applicator (Biuged BGD 209/4) and cured using Spectrolinker™ XL-1500 at 144 mJ/cm² for 96 seconds.

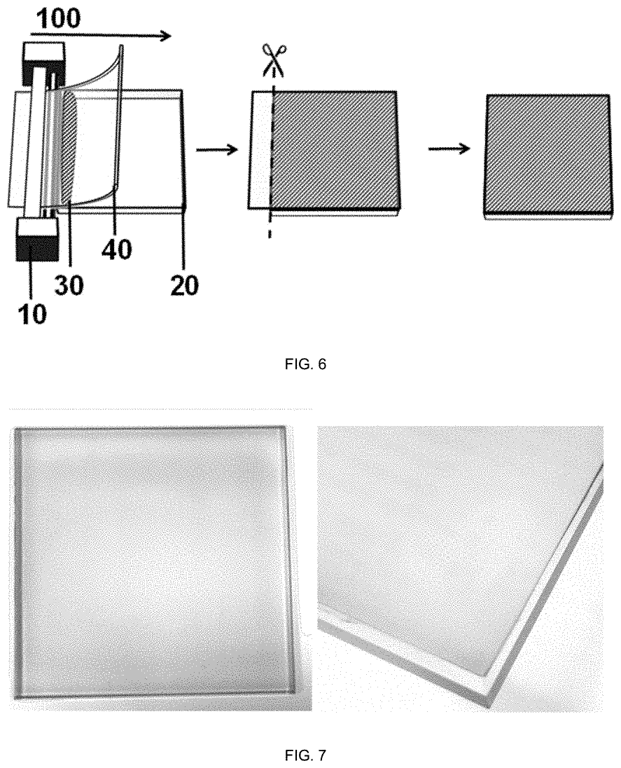

FIG. 6 schematically depicts a general method of coating resin (30) onto a transparent glass (20) using a film applicator (10) in one direction (100). A transparent barrier film (40) was then applied onto the coated resin, with any excess film removed, to give the quantum dots-polymer composite film (60).

### Results

FIG. 7 shows the example of the quantum dots-polymer composite film fabricated using this method. The PLQE was measured by photo-exciting the samples in an integrating sphere, using a Spectra-Physics 405 nm (100 mW, CW) diode laser, and measuring the absorption and photoluminescence using a calibrated Ocean Optics Flame-T and Flame-NIR spectrometer. The PLQE was expected to be reduced slightly by 9-15% (i.e. 26% becoming 17%).

### Example 4

### Implementation of Resonant Energy Transfer Quantum Dot Clusters

To take the concept of energy transfer from giant shell to tiny core further, we also implemented a mixture of InAs/InP/ZnSe/ZnS quantum dots and InP/ZnSe/ZnS quantum dots in a weight ratio of 1:20. The InP/ZnSe/ZnS quantum dots were formed using the same conditions as described above in Example 1, except that the precursors for InP replaced the precursors for InAs in the core-forming reaction step (see Example 1.2 above).

The polymer dispersion containing a mixture of InAs/InP/ZnSe/ZnS quantum dots and InP/ZnSe/ZnS quantum dots in a weight ratio of 1:20 was achieved by using these materials in the process described above in Example 3.

It is believed that the InP based quantum dots will transfer excitation energy to the InAs based quantum dots through a Forster resonance energy transfer mechanism (see FIG. 1) or through a photon recycling mechanism. It is believed that the use of a large amount of InP quantum dots will further enhance visible light absorption and reduce the proportion of InAs required, hence reducing possible reabsorption by the InAs core. In combination with the 1:50 InAs:InP molar ratio in the giant-shell quantum dot, these clusters would have a InAs:InP molar ratio of 1:1000.

### Material and Methods for Examples 5 to 7

1-Octadecene (ODE, 90%, Sigma-Aldrich) was dried with activated molecular sieves in a round-bottom flask (RBF) and degassed under vacuum for 30 min before use. Octylamine (99%, Sigma-Aldrich) and oleic acid (90%, Alfa Aesar) were degassed under vacuum before use. Indium acetate (99.99%, Sigma-Aldrich), zinc acetate (99.99%, Sigma-Aldrich), and tris(trimethylsilyl)phosphine (TMS₃P, 95%, Sigma-Aldrich) were used without further purification. Tris(trimethylsilyl)arsine (TMS₃As) was synthesised in accordance with a previously reported method (Wells, R. L. et. al., Inorg. Synth. 2007, 31, 150). Tris(trimethylsilyl) arsine and tris-(trimethylsilyl)phosphine are pyrophoric and must be handled carefully in a moisture-free and oxygen-free environment. Selenium (99.99%, Sigma-Aldrich), sulfur (99.5%, Sigma-Aldrich), and trioctylphosphine (TOP, 97%, Sigma-Aldrich) were used as purchased.

UV-Visible Absorbance Measurements. UV-visible absorbance spectra were obtained by measuring the transmitted light intensity of an Ocean Optics HL-2000 broadband light source, using an Ocean Optics Flame-T and Flame-NIR spectrometer.

Photoluminescence Quantum Yield Measurements. The photoluminescence spectra and photoluminescence quantum yield were obtained by photoexciting the samples in an integrating sphere, using a Spectra-Physics 405 nm (100 mW, CW) diode laser, and measuring the absorption and photoluminescence using a calibrated Ocean Optics Flame-T and Flame-NIR spectrometer.

### Example 5

Synthesis of InAs—In(Zn)P—ZnSe—ZnS Quantum Dots with One-Pot Continuous Injection Methodology

A new InAs—In(Zn)P—ZnSe—ZnS quaternary giant-shell quantum dot was designed to provide a large Stokes shift and negligible absorption-emission spectral overlap. The InAs—In(Zn)P—ZnSe—ZnS quantum dots were prepared by analogy to Example 1, except that the In(P) shell (as prepared via 1.3) was replaced with the In(Zn)P shell (as prepared via 2.2).

To summarise the preparation procedure (which is provided below), we first prepared a dilute dispersion of InAs cores using indium acetate as the indium precursor, tris(trimethylsilyl)arsine (TMS₃As) as the arsenic precursor, and oleic acid as the ligand. Without purifying the InAs core, we grew a thick shell of In(Zn)P using a 50 times molar ratio of indium acetate and tris(trimethylsilyl)phosphine (TMS₃P) precursors. A 0.5 mol equivalence of zinc acetate (with respect to indium acetate) was added during the InP shell synthesis to enhance the PL of the quantum dots, as guided by previous reports (Thuy, U. T. D., et al., Appl. Phys. Lett. 2010, 97, No. 193104; Pietra, F. et al., ACS Nano 2016, 10, 4754-4762). Indeed, the absence of zinc precursors (InAs—InP—ZnSe—ZnS quantum dots synthesised without Zn doping) resulted in a significantly lower PLQE of 2% under the same reaction conditions.

### 5.1 InAs Core Synthesis

Indium acetate (0.01 mmol, 3 mg) and oleic acid (0.0375 mmol, 13.2 μL) were mixed with ODE (to make 4 mL) in an argon-filled 100 mL RBF. Vacuum was applied to the RBF and the mixture was heated to 60° C. for 30 min under vacuum. The mixture was heated to 210° C. and stirred for 15 min in argon to form a indium precursor clear solution.

TMS₃As (0.005 mmol, 1.5 μL) and octylamine (0.01 mL) were mixed with ODE (to make 1 mL) in an argon glovebox environment. The arsine solution was injected into the indium precursor solution at 210° C. over 10 s. The solution was stirred at 210° C. for 20 min to expend all precursors and complete the InAs core synthesis.

### 5.2 In(Zn)P Shell Synthesis

In a separate RBF, indium acetate (0.5 mmol, 146 mg), zinc acetate (0.25 mmol, 46 mg), and oleic acid (1.9 mmol, 666 μL) were mixed with ODE (to make 10 mL). Vacuum was applied to the RBF and the mixture was heated to 60° C. for 30 min under vacuum. The mixture was heated to 120° C. and stirred for 15 min in argon to form a clear indium precursor solution.

TMS₃P (0.25 mmol, 73 μL) and octylamine (0.5 mL) were mixed with ODE (to make 10 mL) in an argon glovebox environment. The resulting phosphine precursor solution and the indium precursor solution (as prepared above) were each injected into the InAs reaction mixture (as prepared in 5.1; which was still kept at 210° C.), using a syringe pump, at a rate of 0.1 mL/min. The temperature was raised to 220° C. 33 minutes after the precursors were injected, and further raised to 230° C. 66 minutes after the precursors were injected. After complete injection at 100 min, the temperature was raised to 240° C. and the solution was stirred for another 30 min to expend all precursors and complete the In(Zn)P shell synthesis.

### 5.3 ZnSe Shell Synthesis

Selenium (0.1875 mmol, 15 mg) and trioctylphosphine (TOP, 0.1875 mmol, 84 μL) were mixed with ODE (to make 3.75 mL) in a RBF at 120° C. for 30 min under an argon atmosphere. The resulting solution was degassed at 60° C. for 30 min under vacuum to give a TOP-Se precursor.

The TOP-Se precursor solution (3.75 mL) was injected into the reaction mixture (as prepared in 5.2; kept at 240° C.), using a syringe pump, at a rate of 0.15 mL/min. After complete injection at 25 min, the resulting reaction mixture was stirred for another 25 min at 240° C. to expend all precursors and complete the ZnSe shell.

### 5.4 ZnS Shell Synthesis

Sulfur (0.1875 mmol, 6 mg) was mixed with ODE (to make 3.75 mL) in an RBF at 120° C. for 30 min under an argon atmosphere. The resulting solution was degassed at 60° C. for 30 min under vacuum to give a S precursor solution.

Zinc acetate (0.1875 mmol, 34 mg) and oleic acid (0.4687 mmol, 164 μL) were mixed with ODE (to make 3.75 mL) in an RBF. Vacuum was applied to the RBF and the mixture was heated to 60° C. for 30 min under vacuum. The mixture was heated to 120° C. and stirred for 15 min in argon to form a clear zinc precursor solution.

The zinc precursor solution (3.75 mL) and S precursor solution (3.75 mL) were each injected into the reaction mixture (as prepared in 5.3; kept at 240° C.), using a syringe pump, at a rate of 0.15 mL/min. After complete injection at 25 min, the reaction mixture was stirred for another 25 min at 240° C. to expend all precursors and complete the ZnS shell.

### 5.5 Workup and Purification

The reaction solution (as prepared in 5.4) was allowed to cool to room temperature. Ethanol (40 mL) was added to the reaction mixture to precipitate the InAs—In(Zn)P—ZnSe—ZnS quantum dots, followed by centrifugation of the mixture at 10,000 rpm for 5 min. The clear supernatant was carefully removed using a dropper. The addition of ethanol and the centrifugation process were repeated another three times to purify the quantum dots. The final precipitate was redispersed in hexane (20 mL) and stored for further use.

### Results

### Band Gaps

The InAs—In(Zn)P—ZnSe—ZnS quantum dots possess increasing bulk-semiconductor band gaps of 0.35, 1.34, 2.82, and 3.54 eV and decreasing lattice constants of 6.06, 5.87, 5.67, and 5.41 Å, respectively. The sequential decrease in lattice constants allows the lattice strain caused by mismatch to be gradually relaxed across the shell layers.

### Absorption and Photoluminescence

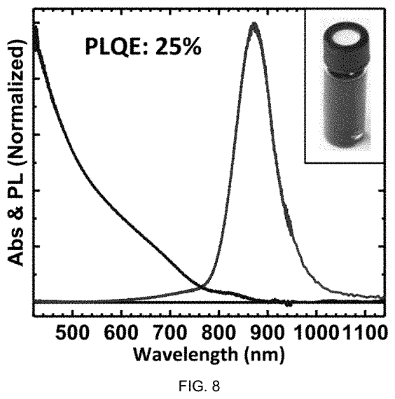

The absorbance and photoluminescence of the InAs—In(Zn)P—ZnSe—ZnS quantum dots is shown in FIG. 8.

We designed the InAs—In(Zn)P—ZnSe—ZnS quantum dots with precursor molar ratios of 1:50:37.5:37.5. The significantly larger In(Zn)P shell absorbs strongly across the entire visible region from 400 to 780 nm and undergoes energy transfer to the InAs core to give NIR emission at 873 nm with a full width at half-maximum of 90 nm (FIG. 8). The spectral width is contributed by a combination of size dispersity and lattice disorder. The quantum dots produced a photoluminescence quantum efficiency (PLQE) of 25%, which is respectable for NIR emitters. The large Stokes shift minimises reabsorption losses and the 873 nm emission is well-matched with the photoresponsive region of silicon solar cells, hence making this quantum dot well-suited for future LSC applications.

The broad visible absorption and the invisible NIR emission give the quantum dots a practical neutral color (FIG. 8 inset) that is useful for implementation in architectural or automotive windows. The material also contains no heavy metals that are regulated by the RoHS Directive and is designed to possess an extremely low arsenic content (˜0.5 atom %), thereby allowing broad applications in consumer products. We note that 873 nm is also a useful wavelength for fluorescence bioimaging due to its weaker absorption and scattering by biological tissues and could therefore be potentially applied to in vivo or in vitro imaging.

### PL Stability

The InAs—In(Zn)P—ZnSe—ZnS quantum dots (0.6 mg/mL in hexane in a 1 cm path-length cuvette, absorption 97%) were subjected to continuous laser irradiation (30 mW, 405 nm) for 6 h. Photoluminescence spectra were obtained at timed intervals, and the peak intensity at 873 nm was plotted against time.

It was observed that there was a minor 2% drop in the PL intensity over 6 h. The results suggest that the quantum dots possess good photostability for their intended applications.

Transmission Electron Microscopy (TEM) and Energy-Dispersive X-ray (EDX) Spectroscopy

The InAs—In(Zn)P—ZnSe—ZnS quantum dots and the intermediate core-shell QDs were imaged using TEM and EDX. TEM images were recorded using a JEOL JEM-2100F Field Emission TEM operated at 200 kV. This system is equipped with an Oxford Instruments INCA EDX. TEM samples were prepared by diluting the quantum dot solutions in hexane, followed by drop casting the solution on a copper grid.

The InAs—In(Zn)P—ZnSe—ZnS quantum dots are irregularly shaped and appear pyramidal in structure (FIGS. 10A and 10B). The quantum dots have a mean size of 9.9 nm (S.D.=1.4 nm) across their longest dimension, which is one of the largest sizes achieved for indium-based dots.

TEM images of the InAs core, InAs—In(Zn)P, and InAs—In(Zn)P—ZnSe (not provided here) reveal an increase in the mean length from 2.8 to 7.6 and 9.6 nm (S.D=0.4; 1.4 and 1.3 nm), respectively. This significant increase in the size of the dots further verifies the formation of an InAs—In(Zn)P core-shell structure.

The energy-dispersive X-ray (EDX) spectrum of the InAs—In(Zn)P—ZnSe—ZnS quantum dots and the intermediate shell layers were measured and their atomic content were tabulated in Table 1. The measured atomic ratio of arsenic to phosphorous is 1:60, generally consistent with the precursor ratios. The indium to phosphorous ratio is 1.7:1, indicating an indium-rich interface with the ZnSe—ZnS shells. This is also a result of the excess indium precursors that were added during synthesis to achieve a higher PL quantum efficiency. We also measured the EDX of the InAs—In(Zn)P dots prior to ZnSe—ZnS growth to determine whether Zn was incorporated into the InP shell. We show in the Table 1 that the Zn content was insignificant at less than 3 atom %, but present nevertheless.

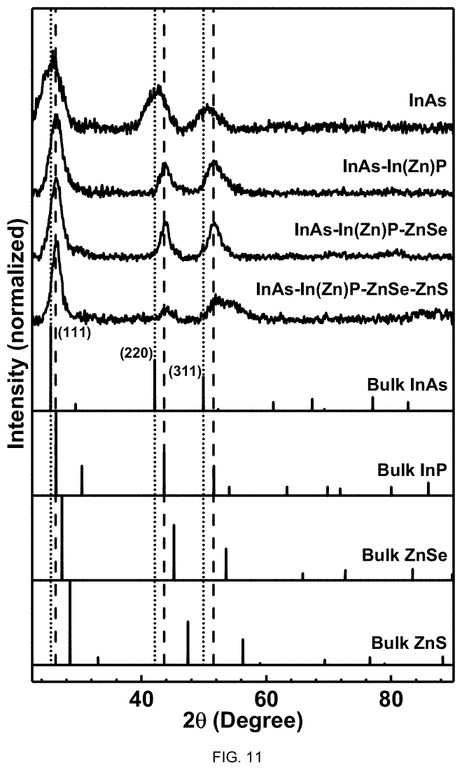

From the EDX data Table 1, the Zn, Se, and S contents are lower compared with the precursor molar ratios, hence suggesting difficulty in growing a thick outer shell. This is likely attributed to a nontrivial lattice mismatch between the layers, as supported by the X-ray diffraction (XRD) data in FIG. 11.

TABLE 1
Table showing the atomic percentage composition of In, As, P, Zn, and Se as determined
by energy-dispersive X-ray (EDX) spectroscopy for the InAs, InAs—In(Zn)P and
InAs—In(Zn)P—ZnSe intermediate core-shell QDs and InAs—In(Zn)P—ZnSe—ZnS QDs.

| | Atomic % | | | | Precursor |
|---|---|---|---|---|---|
| Element | InAs | InAs—In(Zn)P | InAs—In(Zn)P—ZnSe | InAs—In(Zn)P—ZnSe—ZnS | ratio |
| In | 79.4 | 57.4 | 60.0 | 52.3 | 100 |
| As | 20.6 | 0.6 | 0.5 | 0.5 | 1 |
| P | — | 39.3 | 32.4 | 30.5 | 50 |
| Zn | — | 2.7 | 3.9 | 8.6 | 50 |
| Se | — | — | 3.2 | 5.4 | 37.5 |
| S | — | — | — | 2.7 | 37.5 |

### X-ray Diffraction (XRD)

X-ray diffraction (XRD) measurements were performed on the InAs—In(Zn)P—ZnSe—ZnS quantum dots and the intermediate shell layers (FIG. 11). Powder X-ray diffractograms were obtained using Bruker D8 ADVANCE with an X-ray source of wavelength 1.5405 Å (Cu Kα1 line). Each XRD sample was prepared by drop casting the colloidal QD solution onto a standard single crystal Si zero-diffraction support plate and left to dry overnight.

An increase in the 2θ values of the XRD peaks toward the bulk InP material was observed after the completion of the In(Zn)P precursor injection, indicating the formation of an In(Zn)P shell overcoating the InAs core (Yun-Wei, C.; Uri, B. Angew. Chem., Mt. Ed. 1999, 38, 3692-3694). The narrowing of the XRD peaks from the InAs to the InAs—In(Zn)P quantum dots also suggests a larger crystallite size due to the formation of the In(Zn)P shell. However, a negligible shift in the XRD peaks to higher 2θ values was observed after the ZnSe and ZnS shell precursor injections, thereby reflecting their thin growth due to lattice mismatch and resulting in a modest final PLQE of 25%. Nonetheless, the observed spike in the PLQE from 10% after the In(Zn)P shell growth to 25% in the final quantum dot product despite the thin ZnSe and ZnS shells emphasises the importance of these outer layers in enhancing the photoluminescence and photostability of the final synthesised multishell quantum dots.

### Example 6: Effect of Speed of Injection

InAs—In(Zn)P—ZnSe—ZnS quantum dots were synthesised in accordance with the procedure in Example 5, except a 2× continuous injection speed (0.2 mL/min) was used in 5.2, instead of 0.1 mL/min.

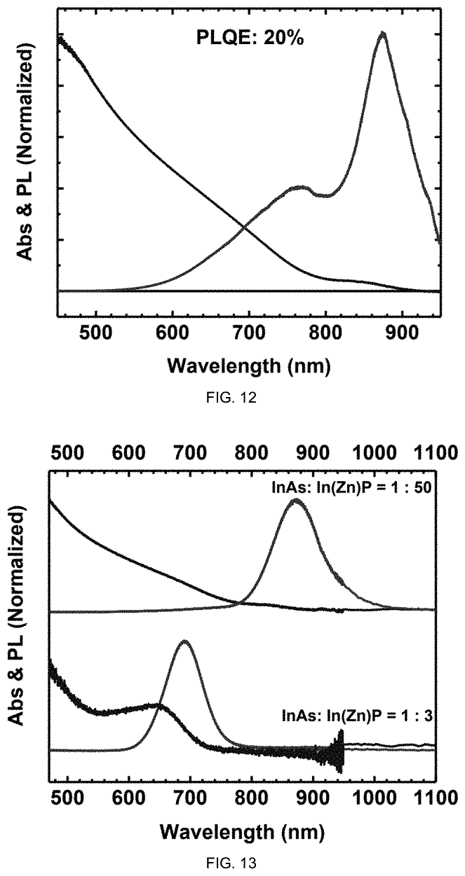

The absorbance and photoluminescence spectra of the quantum dots synthesised with an injection speed of 0.2 mL/min is shown in FIG. 12. A large shoulder peak was observed at shorter wavelengths, indicating the nucleation and growth of new InP cores. In contrast, a slow injection of 0.1 mL/min ensured that the precursor concentration in the reaction mixture remained low at all times, such that growth onto existing cores was favored compared with new nucleation events.

### Example 7: Effect of Shell Growth on Absorbance and Photoluminescence

The procedure in Example 5 was repeated and the progress of the reaction was tracked by extracting small aliquots from the reaction mixture at timed intervals and by measuring their UV-visible absorbance and PL characteristics.

### Absorbance

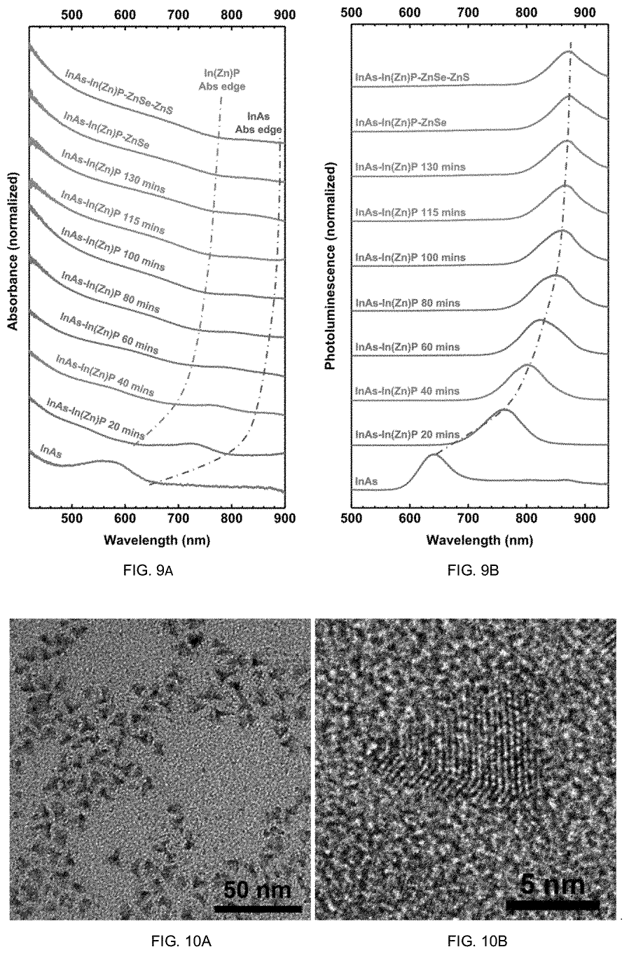

The absorbance spectra of the reaction mixture as a function of reaction time were plotted and the absorption edge of the InAs core and In(Zn)P shell were traced as the layers were progressively grown (FIG. 9A).

The absorption edge of the InAs core was first observed at 650 nm, but quickly shifts to 790 nm upon the first 20 min of In(Zn)P growth. This InAs absorption edge gradually red shifts to 890 nm and weakens considerably as the In(Zn)P growth continued through the continuous injection of precursors. The red shift of the InAs spectrum is a signature of the extension of the electronic wave function into the In(Zn)P shell, and the weakening of the absorption edge is due to the decreasing contributions by InAs as the 50 times larger In(Zn)P shell was grown. In the same plot, we observe the appearance of the In(Zn)P absorbance edge at 620 nm after the first 20 min of shell growth. This is followed by a progressive red shift to 780 nm and a strengthening of the absorption intensity over the remaining duration of the In(Zn)P giant-shell growth. Upon completion of the In(Zn)P shell growth, additional layers of ZnSe and ZnS shells were grown through the continuous injection of the trioctylphosphine-selenium (TOP-Se) precursor solution, followed by the continuous injection of zinc acetate, oleic acid, and sulfur precursor solutions. The comparison plots in the FIG. 13 confirm a distinct reduction in spectral overlap and an increase in Stokes shift upon the growth of the thick shell layers.

### Photoluminescence

FIG. 9B shows the evolution of PL spectra during the process of InAs—In(Zn)P—ZnSe—ZnS quantum dot synthesis. The InAs PL peak first appeared at 641 nm, but quickly shifted to 762 nm upon 20 min of In(Zn)P shell growth. The PL peak red-shifted further as a thicker In(Zn)P shell was grown, finally ending at 873 nm. These observations are in line with the absorbance spectral characteristics.

It is worth noting that our PL measurements were performed in dilute aliquots where the QDs are independent and spatially separated. The presence of only a single emission peak in all samples therefore confirms that the In(Zn)P was grown as shells that are necessarily in close proximity to the InAs for energy transfer to occur. There was negligible nucleation and growth of independent In(Zn)P cores under our reported reaction conditions, since a separate In(Zn)P PL at a shorter wavelength was not observed. This validates the importance of a continuous injection approach (Franke, D. et. al., Nat. Commun. 2016, 7, No. 12749), whereby the In(Zn)P precursors were always maintained at a low concentration in the reaction flask to mitigate the chances of undesired In(Zn)P nucleation events. We note that it is very unlikely for the 873 nm emission to be attributed to In(Zn)P core-based QDs (without InAs), given that the highest wavelength reported for such systems is 750 nm (Xie, R. et al., J. Am. Chem. Soc., 2007, 129, 15432-15433). The subsequent ZnSe and ZnS shells resulted in the enhancement of the PL intensity due to the passivation of surface defects, but caused no significant changes to the spectral characteristics.

1. Luminescent nanoparticles comprising:
In₁₋ₓZnₓAs; and
In_{1-y}Zn_{y}P, wherein
x is from 0 to 0.5, such as from 0.02 to 0.33;
y is from 0 to 0.6, such as from 0.02 to 0.5; and
the molar ratio In₁₋ₓZnₓAs to In_{1-y}Zn_{y}P is from 1:4 to 1:5000.

2. The nanoparticles according to claim 1, wherein x is 0 or y is 0, or x and y are both 0.

3. The nanoparticles according to claim 1, wherein the nanoparticles further comprise one or more of ZnSeS, ZnSe, and ZnS.

4. The nanoparticles according to claim 3, wherein the molar ratio of In to Zn is from 0.1 to 1 to 10:1.

5. The nanoparticles according to claim 1, wherein the nanoparticles are selected from one or more of:
(a) InAs and InP;
(b) InAs, InP and ZnSe;
(c) InAs, InP and ZnS;
(d) InAs, InP, ZnSe and ZnS; and
(e) In₁₋ₓZnₓAs, In_{1-y}Zn_{y}P and ZnSeS, where x is from 0.02 to 0.33 and y is from 0.02 to 0.5.

6. The nanoparticles according to claim 1, wherein the nanoparticles have a photoluminescence peak and an absorption edge, where the photoluminescence peak is red-shifted from 50 to 250 nm away from the absorption edge.

7. The nanoparticles according to claim 6, wherein the photoluminescence peak is from 700 to 1100 nm.

8. The core-shell nanoparticle according to claim 6, wherein the absorption edge is from 600 to 1000 nm.

9. The nanoparticles according to claim 1, wherein the nanoparticles are core-shell nanoparticles.

10. The nanoparticles according to claim 9, where the nanoparticles comprise:
a core of In₁₋ₓZnₓAs and a shell layer of In_{1-y}Zn_{y}P surrounding the In₁₋ₓZnₓAs core, wherein the molar ratio In₁₋ₓZnₓAs to In_{1-y}Zn_{y}P is from 1:4 to 1:5000; or
a core of In_{1-y}Zn_{y}P and a shell layer of In₁₋ₓZnₓAs surrounding the In_{1-y}Zn_{y}P core, wherein the molar ratio In_{1-y}Zn_{y}P to In₁₋ₓZnₓAs is from 1:4 to 1:5000, wherein:
x is from 0 to 0.5; and
y is from 0 to 0.6.

11. The nanoparticles according to claim 10, wherein:
the In₁₋ₓZnₓAs core has a diameter of from 10 to 50 Å; or
the In_{1-y}Zn_{y}P core has a diameter of from 30 to 110 Å.

12. The nanoparticles according to claim 10, wherein one or more of the following apply:
the nanoparticle has a diameter of from 2 to 100 nm;
x is 0; and
y is 0.

13. The nanoparticles according to claim 10, wherein the nanoparticle further comprises one or more shells selected from ZnSeS, ZnSe, and ZnS.

14. The nanoparticles according to claim 10, wherein the nanoparticles have a structure selected from one or more of:
(a) InAs/InP;
(b) InAs/InP/ZnSe;
(c) InAs/InP/ZnS;
(d) InAs/InP/ZnSe/ZnS; and
(e) In₁₋ₓZnₓAs/In_{1-y}Zn_{y}P/ZnSeS, where x is from 0.02 to 0.33 and y is from 0.02 to 0.5.

15. The nanoparticles according to claim 10, wherein one or both of the following apply:
in the In₁₋ₓZnₓAs core or shell layer, the molar ratio of In₁₋ₓZnₓ to As is from 5:1 to 1:1; and/or
in the In_{1-y}Zn_{y}P core or shell layer, the molar ratio of In_{1-y}Zn_{y} to As is from 5:1 to 1:1.

16. A composite material comprising:
a luminescent nanoparticle material according to claim 1; and
a polymeric material, wherein the luminescent nanoparticle material is homogeneously dispersed throughout a matrix formed by the polymeric material.

17. The composite material according to claim 16, wherein the polymeric material is a vinyl polymer or copolymer.

18. A luminescent solar concentrator comprising a layered material having at least one edge, wherein the layered material comprises at least one layer of a composite material according to claim 16 sandwiched between at least two transparent substrate layers.

19. The solar concentrator according to claim 18, wherein the at least two transparent substrate layers are selected from one or more of glass, a polymeric material and combinations thereof.

20. (canceled)

21. A method of forming a core-shell luminescent nanoparticle, which method comprises:
providing a core of In₁₋ₓZnₓAs and forming a first shell of In_{1-y}Zn_{y}P on the In₁₋ₓZnₓAs core; or
providing a core of In_{1-y}Zn_{y}P and forming a first shell of In₁₋ₓZnₓAs on the In_{1-y}Zn_{y}P core, wherein:
the molar ratio In₁₋ₓZnₓAs to In_{1-y}Zn_{y}P is from 1:4 to 1:5000;
x is from 0 to 0.5; and
y is from 0 to 0.6.
